(19) United States
(12) Patent Application Publication
(10) Pub. No.: US 2022/0091275 A1
(43) Pub. Date: Mar. 24, 2022

(54) A METHOD AND A SYSTEM FOR ASSESSING ASPECTS OF AN ELECTROMAGNETIC SIGNAL

(71) Applicant: SABER ASTRONAUTICS AUSTRALIA PTY. LTD., Chippendale (AU)

(72) Inventors: Jason Held, Chippendale (AU); Aidan O'Brien, Chippendale (AU); Andreas Antoniades, Chippendale (AU)

(21) Appl. No.: 17/292,668

(22) PCT Filed: Nov. 23, 2019
(86) PCT No.: PCT/AU2019/051289

§ 371 Date: May 10, 2021

(30) Foreign Application Priority Data
Dec. 6, 2018 (AU) 2018904632

(51) Int. Cl. G01S 19/14; G01S 19/21; G01S 19/39; G06K 9/00

(52) U.S. Cl. CPC G01S 19/14; G01S 19/21; G06K 9/00536; G06K 9/00523; G01S 19/396

(57) ABSTRACT

A method of assessment of aspects of one or more electromagnetic signals, the method including, in an electronic processing device: receiving one or more data feeds relating to one or more of: cosmic, atmospheric, and local environmental conditions; receiving one or more data feeds relating to the one or more electromagnetic signals; determining a plurality of metrics at least partially using the one or more data feeds; and, identifying a likely source of interference in the electromagnetic signals by assessing relationships among the plurality of metrics.

### TECHNICAL FIELD

The present technology relates generally to electromagnetic signal assessment. Embodiments of the technology find particularly effective application in radio-frequency electromagnetic signals. In some embodiments there is particularly effective application of the technology in the detection of interference, and the identification of the types of interference, with radio signals. Certain embodiments find effective application in assessment of satellite radio signals, although in some embodiments, terrestrial radio signals can also be assessed.

### BACKGROUND

Known satellite radio-frequency signal receivers experience degradation to signal in various situations, including over-the-horizon SATCOM and GPS line of sight.

In a recent mission. the applicant company was operating a dish at 915 MHz and experienced interference with cell phone towers using nearby frequencies. The applicant experienced difficulties in differentiating the signal from the tower signal.

Known radio signal processing and assessment methods are inadequate and inflexible. They are slow to resolve and/or are unable to directly detect interference.

There can be multiple effects on electromagnetic signals received at the Earth's surface.

Some effects can be detected with known systems, but those systems do not provide enough information; or soon enough; to be of utility in a rapidly changing environment.

For example, it is known that geomagnetic storms can damage technical infrastructure. Detection systems have been proposed, but they can be cheap and insensitive at the accessible end, which is ineffective, or, at the other end, overly complex, which can delay reporting of results, reducing the utility of the detection mechanism.

It can be seen that modelling of known systems is inadequate.

There are times when information to inform a model is not available and in those or similar situations, known signal assessment systems have been found to fail.

The present inventors have invented a new system for assessing electromagnetic signals to produce more information about the signal than is provided by known systems, or at least provides an alternative.

### SUMMARY OF THE INVENTION

Broadly, the present technology provides a method of modelling in real-time, one or more of a plurality of deleterious effects on an electromagnetic signal.

Broadly, the present technology also provides a method of classifying electromagnetic signal interference into a plurality of types, including intentional, unintentional and/or environmental interference. Embodiments of the technology further assess the signal interference into sub-classifications including local weather, remote weather, or cosmic weather and other classifications.

Broadly, the present technology yet further provides assessment of a radio signal to identify the absolute and/or relative magnitude of the contribution to the signal of one or more types of interference.

Broadly, the present technology provides autonomous assessment of signal so as to classify one or more types of interference and quantify the contribution of those one or more types of interference, to a radio signal.

The present technology, in one aspect, provides a method of assessment of aspects of one or more electromagnetic signals, the method including the steps of:

receiving in a computer processor, one or more data feeds relating to one or more of:

cosmic conditions, atmospheric conditions, signal receiver characteristics, and local meteorological and/or environmental conditions;

receiving in a computer processor, one or more data feeds relating to the one or more electromagnetic signals;

mapping, in a computer processor, the data from the data feeds into metrics;

identifying, by, use of a computer processor, likely sources of interference in the electromagnetic signal by assessing relationships between selected metrics over time.

In one embodiment the data includes observable characteristics of the electromagnetic signal receiver such as for example attitude, height, vibration, temperature, frequency response, power.

In one embodiment the mapping step includes the step of mapping with a Systems of Systems (SoS) approach in order to encapsulate the data feeds into metrics.

In one embodiment a System of Systems (SoS) Metric Map is constructed. In that arrangement, the interactions between metrics are identified by the regression techniques to form the System Map, which allows causal comprehension between different metrics.

In one embodiment functional attributes are quantified from the interactions of its metrics to form a System Map, which facilitates probabilistic inference scaling between SOS properties and behaviours, and individual metrics.

In one embodiment the mapping step includes a normalising step to normalise a metric to an index or common unit, so as to facilitate comparison between other metrics.

In one embodiment the normalising step includes resolving the regressions with one or more numerical techniques.

In one embodiment the statistical tools include one or more regression analyses.

In one embodiment the normalising step includes deploying statistical tools to normalise the metrics onto a common scale.

In one embodiment, the normalising step provides a metric with a unit value of between 0 and 1 for ease of comparison of metrics, depending on the numerical or algorithmic method selected for regression.

In one embodiment the normalising step uses raw values normalised by an absolute maximum, again, depending on the numerical method selected for regression.

In one embodiment the normalising step is conducted by numerical conversion.

In one embodiment the normalising step is conducted by, machine learning models.

In one embodiment the metrics are formulated from data indicative of any one or more of: local magnetic field; space weather; electromagnetic signal quality, electromagnetic signal receiver quality, GPS position accuracy; and GPS.

In one embodiment the one or more numerical techniques includes deploying one or more machine learning algorithms in a computer processor to identify likely relationships between the metrics and/or between time steps.

In one embodiment the machine learning is supervised, in that it extrapolates from known interference and known signal degradation types using one or more historical data feeds and signals, to seek likely relationships between metrics in relation to new electromagnetic signal data points combined with one or more new data points in the data feeds.

In one embodiment the machine learning is unsupervised.

In one embodiment the identification step includes a clustering regression step wherein time steps in the data feeds are classified by conducting numerical regression using a regression engine disposed within a computer processor. In one embodiment the clustering regression is conducted by K-means clustering, and/or Mean-shift clustering, and/or DBSCAN, and/or Expectation Maximisation by Gaussian Mixture Modelling, and/or Agglomerative Hierarchical clustering. This is a qualitative relationship identification step between a plurality of metrics.

In one embodiment, the identification step also includes numerical relationship regression for each cluster in a computer processor, to identify the strength of the qualitative relationships between a plurality of normalised metrics which had been identified in the clustering regression step. This is a quantitative relationship identification step.

In embodiments the relationship regression model utilises a plurality of metric dusters as inputs to the regression. In one embodiment the number of inputs is typically more than four, however any suitable number of dusters may be used depending upon the particular metrics, application and the like. There may be a greater number of inputs provided to the model, depending on the complexity of the model and its stability with more duster inputs.

In one embodiment the number of inputs is determined in accordance with a tuning algorithm. For instance, the tuning algorithm may compare accuracy of the identification step as the number of metric dusters is varied over a range. The number of metric dusters may then be selected in accordance with any one or more of the determined accuracies, computational requirements, and/or the like.

In one embodiment the identification step further includes the step of constructing graphical representation of one or more relationships between metrics for display on a display device. In one embodiment the graphical construction is of one or more directed acyclic graphs on a display device in order to assess weights of influence between a plurality of metrics. In one embodiment the weights are represented in matrix format.

In one embodiment the regression techniques include Dynamic Bayesian Network and/or Gaussian Mixture Modelling.

In one embodiment the method includes the step of storing the duster regression and the relationship regression for later analysis. In one embodiment the method includes the real-time use of the cluster regression and the relationship regression during realtime analysis of the electromagnetic signal.

In one embodiment the assessment of signal relationships over time involves a comparison of stored or otherwise loaded cluster regression and relationship regression results, with new data received.

In one embodiment the assessment step also includes conversion of new data into metrics.

In one embodiment the assessment step additionally includes classification of a new metric by matching the metric to the relevant cluster.

In one embodiment the assessment step further includes validation of the cluster by predicting the timestep with the stored or loaded relationship regression result.

In one embodiment the data feeds include data relating to local temperature, cosmic radiation, atmospheric radiation.

In one embodiment the data feeds are directly from sensors onboard or wirelessly or directly connected to the computer processor.

In one embodiment the data feeds are indirectly provided, via an aggregator remote from the computer processor.

In one embodiment the electromagnetic signal is one which is received by a device disposed in a selected location on or near the Earth's surface.

In one embodiment the electromagnetic signal is a radio frequency signal from one or more satellites or aircraft.

In one embodiment the radio frequency signal relates to terrestrial position data obtained from one or more satellites or aircraft.

In one embodiment there is provided the step of assessing in a computer processor, the quality of the signal from the aggregator.

In accordance with another aspect of the present technology, there is provided a device for assessing aspects of an electromagnetic signal, the device including:

one or more receivers for receiving one or more data feeds from one or more sources relating to cosmic, atmospheric and/or local environmental conditions;

one or more receivers for receiving data relating to one or more electromagnetic signals;

a mapping engine for mapping performance metrics derived from the data feeds to facilitate their comparison; and

an assessment engine for assessing relationships between the mapped performance metrics so as to identify likely sources of signal changes.

In a father broad form, the present invention seeks to provide a method of assessment of aspects of one or more electromagnetic signals, the method including, in an electronic processing device: receiving one or more data feeds relating to one or more of: cosmic, atmospheric, and local environmental conditions;

receiving one or more data feeds relating to the one or more electromagnetic signals;

determining a plurality of metrics at least partially using the one or more data feeds; identifying a likely source of interference in the electromagnetic signals by assessing relationships among the plurality of metrics.

In one embodiment, the one or more data feeds are at least partially indicative of observable characteristics of an electromagnetic signal receiver.

In one embodiment, the observable characteristics include any one or more of an altitude, a height, a vibration, a temperature, frequency response, and power.

In one embodiment, the method includes, in the electronic processing device, determining a reference model at least partially indicative of relationships among metrics, the reference model being usable in assessing the relationships.

In one embodiment, the reference model is generated using a System or Systems (SoS) approach.

In one embodiment, generating a reference model includes using one or more regression methods, wherein the relationships are at least partially indicative of causality.

In one embodiment, generating the reference model includes quantifying functional attributes using the relationships.

In one embodiment, the reference mod& includes a system of systems (SoS) model.

In one embodiment, wherein the method includes, in the processing device, normalizing the metrics.

In one embodiment, the normalizing includes performing at least one regression using at least one numerical technique.

In one embodiment, the normalizing includes using at least one statistical tool to normalize the metrics, each of the at least one metric being scaled according to a common scale.

In one embodiment, the common scale includes a numerical range between 0 and 1.

In one embodiment, the normalizing includes normalizing raw values of the at least one data feed and an absolute maximum of the raw values.

In one embodiment, the normalizing includes numerical conversion.

In one embodiment, the normalizing is at least partially performed using one or more machine learning models.

In one embodiment, the one or more metrics is determined at least in part using data indicative of at least one or more of a local magnetic field, space weather, an electromagnetic signal quality, an electromagnetic signal receiver quality, a GPS position accuracy and a GPS.

In one embodiment, the identification includes determining at least one machine learning algorithm to thereby assess relationships between at least one of: the metrics; and, a time step.

In one embodiment, the machine learning algorithm is supervised.

In one embodiment, the machine learning is unsupervised.

In one embodiment, the identification includes clustering the metrics to thereby deter mine at least one state in accordance with the determined clusters, the state being at least partially indicative of a qualitative relationship between metrics.

In one embodiment, the clustering includes performing, in the computer processor, at least one of k-means clustering, mean-shift clustering, DBSCAN, expectation maximization by Gaussian mixture modelling, and agglomerative hierarchical clustering.

In one embodiment, the reference model includes an at least partially trained machine learning model.

In one embodiment, the determining the reference model includes at least one of: generating the reference model;

receiving the reference model from a remote processing device; and,

retrieving the reference model from a store.

In one embodiment, generating the reference model includes training the reference model using at least one of:

at least one of the plurality of metrics; and,

at least one pre-determined metric.

In one embodiment, generating the training includes at least one of online and offline training.

In one embodiment, the reference model is indicative of qualitative and quantitative relationships among metrics.

In one embodiment, the reference model is at least partially indicative of causality among the relationships.

In one embodiment, the reference model includes at least one feature extraction reference model and at least one regression reference model.

In one embodiment, the identifying includes, in the electronic processing device, per forming a numerical relationship regression for at least one of the clusters to thereby at least partially determine a causal relationship.

in one embodiment, method includes, in the processing device, identifying the source of interference using at least one of the state and the causal relationship.

In one embodiment, the identification includes, in the computer processor, generating a representation indicative of at least one of:

the at least one state; and,

the at least one causal relationship.

In one embodiment, the method includes, in the computer processor, displaying the representation on a display.

In one embodiment, the representation includes a directed acyclic graph (DAG) indicative, of the causal relationship.

In one embodiment, the representation includes a graphical representation indicative of the DAG.

In one embodiment, the representation includes a matrix indicative of the DAG.

In one embodiment, the regression techniques include at least one of a Dynamic Bayesian Network and a Gaussian Mixture Model.

In one embodiment, the method includes, in the computer processor, storing results of at least one of cluster regression and relationship regression.

In one embodiment, the method includes, in the computer processor, determining at least of the pre-determined cluster regression and the relationship regression, and performing the identifying in real-time using the predetermined duster regression and/or the relationship regression.

In one embodiment, the method includes, in a computer processor, assessing the quantitative relationship indicators over time by comparing at least one of the predetermined duster regression and the predetermined relationship regression with at least one of the duster regression and the relationship regression, respectively.

In one embodiment, the data feeds include data indicative of at least one of a local temperature, cosmic radiation and atmospheric radiation.

In one embodiment, the data feeds are at least partially received from sensors in electrical communication with the computer processor.

In one embodiment, the data feeds received via an aggregator remote from the computer processor.

In one embodiment, the electromagnetic signal is at least partially received by a device disposed in a selected location on or near the Earth's surface.

In one embodiment, the electromagnetic signal is a radio frequency signal.

In one embodiment, the radio frequency signal is received from one or more satellites or aircraft.

In one embodiment, the radio frequency signal relates to terrestrial position data obtained from one or more satellites or aircraft.

In one embodiment, the method includes, in a computer processor, determining quality of at least one of the signal and the data feeds from an aggregator.

In a further broad form, the present invention seeks to provide a method for at least partially identifying at least one source of interference associated with the electromagnetic, the method according to any of the examples herein.

In a further broad form, the present invention seeks to provide a system for assessing aspects of an electromagnetic signal, the system including;

one or more receivers for receiving one or more data feeds from one or more sources relating to cosmic, atmospheric and/or local environmental conditions; one or more receivers for receiving data relating to one or more electromagnetic signals; a mapping engine for mapping metrics derived from the data feeds; and

a regression engine for assessing relationships between selected mapped metrics so as to identify likely sources of signal changes.

These are significant improvements over known technology, in part shown in the examples and results obtained in testing.

Clarifications

In this specification, where a document, act or item of knowledge is referred to or discussed, this reference or discussion is not an admission that the document, act or item of knowledge or any combination thereof was at the priority date:

(a) part of common general knowledge; or

(b) known to be relevant to an attempt to solve any problem with which this specification is concerned.

It is to be noted that, throughout the description and claims of this specification, the word ‘comprise’ and variations of the word, such as ‘comprising’ and ‘comprises’, is not intended to exclude other variants or additional components, integers or steps.

### BRIEF DESCRIPTION OF THE DRAWINGS

In order to enable a clearer understanding, a preferred embodiment of the technology will now be further explained and illustrated by reference to the accompanying drawings, in which:

FIGS. 1A and 1B are schematic drawings of systems of embodiments of the technology;

FIG. 2 is a schematic drawing of a computer processor which may implement one or more steps of embodiments of the technology;

FIG. 3 is a flowchart of a method of an embodiment of the technology;

FIG. 4 is a snapshot of results of an Example, 1 implementation of the technology, and in particular, a graphical representation of an example measured and predicted metric relating electronic SPWX (blue) with prediction (red);

FIG. 5 is a snapshot of results of the Example 1 implementation of FIG. 4, including a graphical representation of an example measured and predicted metric relating alpha SPWX (blue) with prediction (red);

FIG. 6 is a snapshot of results of the Example 1 implementation of FIG. 4, including a graphical representation of an example measured and predicted metric relating to GPS constellation strength (blue) with prediction (red);

FIG. 7 is a snapshot of results of the Example 1 implementation of FIG. 4, including a graphical representation of an example measured and predicted metric relating to GPS position accuracy (blue) with prediction (red);

FIG. 8 is a snapshot of results of the Example 1 implementation of FIG. 4, including a graphical representation of an example measured and predicted metric relating to local infra-red (IR) at the GPS receiver strength (blue) with prediction (red);

FIG. 9 is a snapshot of results of the Example 1 implementation of FIG. 4. including a graphical representation of an example state number used at each time step in the model;

FIG. 10 is a snapshot of results of the Example 2 implementation of the technology, including a graphical representation of an example measured and predicted metric 14 relating to signal-to-noise (SNR) performance (blue) with prediction (red) during training;

FIG. 11 is a snapshot of results of the Example 2 implementation of FIG. 10, including a graphical representation of an example measured and predicted metric relating to SNR performance (blue) with prediction (red) after training, with anomalies at

FIG. 12 is a snapshot of results of Example 2 implementation of FIG. 10, including a graphical representation of an example measured and predicted metric 34 relating to position uncertainty (blue) with prediction (red) at run-time;

FIG. 13 is a snapshot of results of Example 3 implementation, including a graphical representation of an example measured and predicted metric relating to SNR performance (blue) with prediction (red);

FIG. 14 is a snapshot of results of Example 3 implementation of FIG. 13, including a graphical representation of an example measured and predicted metric relating to local magnetic field (blue) with prediction (red);

FIG. 15 is a snapshot of results of Example 3 implementation of FIG. 13, including a graphical representation of an example measured and predicted metric 34 relating to position accuracy (blue) with prediction (red);

FIG. 16 is a snapshot of results of FIG. 15 at higher resolution;

FIG. 17 are snapshots of the results of Example 4 which is an embodiment of the technology, including example measured (blue) and predicted (red) metrics relating to: (upper left)) M1 current on the spark gap. (upper right) M34 position accuracy, (lower left) M2 SNR, (lower right) M10 local magnetic field;

FIG. 18 is a snapshot of the results of Example 5, which is an embodiment of the technology, including a graphical representation of the GMM state selected by the model at each time step;

FIG. 19 is a schematic diagram of an example of a dataflow of a method for assessment of aspects of electromagnetic signals;

FIG. 20 is a schematic diagram of an example of a dataflow of a method for generating a synthetic signal;

FIG. 21A is a snapshot of a waterfall plot of a frequency spectrum of a synthetic signal generated according to an example of the method of FIG. 20;

FIG. 21 Bis a snapshot of a waterfall plot of a frequency spectrum of a real waveform according with the synthetic example of FIG. 21A;

FIGS. 22A and 22B are snapshots of power spectral densities of an example of a recorded signal and the same signal sample including synthetic Gaussian noise, respectively;

FIG. 23 is a schematic diagram of an example of dataflow of a method for training a mod& for identifying an electromagnetic signal;

FIG. 24 is a snapshot of a confidence matrix of predicted vs actual signal label generated using an example of the model of FIG. 23;

FIG. 25 is a schematic diagram of an example of dataflow of a method for identifying an electromagnetic signal;

FIG. 26 is a snapshot of a waterfall plot of a frequency spectrum of a signal sampled using an example of the method of FIG. 25;

FIG. 27 is a graphical representation of an example of accuracy scores based on the sum of KL-Divergence across all metrics, for each GMM mixture in the system map of Example 6;

FIG. 28 is a snapshot of a graphical representation of an example measured and predicted metric of Example 6 relating GPS satellite visibility, comparing metric (solid blue) with prediction (dotted red), captured using field loggers and showing several interference events;

FIGS. 29A and 29B are snapshots of graphical representations of examples of measured and predicted metrics determined in Example 6 relating to number of satellites in view and size of GPS uncertainty, respectively, comparing metric (solid blue) with prediction (dotted red);

FIG. 30 is a snapshot of a graphical representation of an example measured and predicted metric of Example 6 relating to GPS signal to noise (SNR) accuracy, comparing metric (solid blue) with prediction (dotted red);

FIG. 31 is a snapshot of a graphical representation of an example measured and predicted metric of Example 6 relating to GPS Position Dilution of Precision (PROP) accuracy, comparing metric (solid blue)) with prediction (dotted red);

FIG. 32 is a snapshot of a graphical representation of an example measured and predicted metric of Example 6 relating to GPS signal to noise (SNR) accuracy of Satellite 3, comparing metric (solid blue) with prediction (dotted red);

FIG. 33 is a snapshot of a graphical representation of an example measured and predicted metric of Example 6 relating to GPS point distance uncertainty, comparing metric (solid blue) with prediction (dotted red);

FIG. 34 is a snapshot of a graphical representation of an example measured and predicted metric of Example 6 relating to GPS altitude distance uncertainty, comparing metric (solid blue) with prediction (dotted red);

FIG. 35 is a graphical representation of an example of accuracy scores based on the sum of KL-Divergence across all metrics, for each GMM mixture in the system map of Example 7;

FIG. 36 is a snapshot of a graphical representation of an example measured and predicted metric of Example 7 relating to the probability of (Ultra-High Frequency Voice) UHFV, comparing metric (solid blue) with prediction (dotted red);

FIG. 37 is a snapshot of a graphical representation of examples measured and predicted metrics of Example 7 relating to the probability of UHFV, comparing clear UHFV metric (solid blue), predicted clear UHFV (dotted green), UHFV with Gaussian noise metric (solid orange) and UHFV with Gaussian noise predicted (dotted red);

FIG. 38 is a snapshot of a graphical representation of an example measured and predicted metric of Example 7 (and FIG. 35) relating to the probability of (Ultra-High Frequency Voice) UHFV with Gaussian noise, comparing metric (solid blue) with prediction (dotted red);

FIG. 39 is a snapshot of a graphical representation of a state vector of Example 7 including a further time series interference simulation (Gaussian UHFV), where state 3 is UHFV without Gaussian noise:

FIG. 40 is a snapshot of a graphical representation of accuracy convergence rollups of individual metrics in the GPS system map of Example 6;

FIG. 41 is a snapshot of a graphical representation of accuracy convergence rollups of individual metrics in the CNN system map of Example 7;

FIGS. 42A and 42B are snapshots of graphical representations of example measured and predicted metrics of Example 6 relating to of GPS vertical dilution of precision (VDOP) of the training and test data set, respectively;

FIG. 43 is a screenshot of an example of a user interface for displaying a metric relationship tree, stream of data, and metric prediction performance;

FIG. 44 is a screenshot of the user interface of FIG. 43 including the ability to define start and stop times for the data while allowing for real-time tick data; and

FIG. 45 is a schematic of an example of dataflow of a method for training and using a GMM and DBN model to assess a GPS signal.

### DETAILED DESCRIPTION

An example of a method of assessing aspects of one or more electromagnetic signals will now be described. In this example, the method is performed by an electronic processing device, such as will be described in further detail below.

The method includes receiving one or more data feeds relating to cosmic, atmospheric, and/or local environmental conditions. In addition, the method includes receiving one or more data feeds relating to the one or more electromagnetic signals. The data feeds may be received in any suitable manner, as will be discussed further below, including via sensors, remote processors, and/or by at least partially generating the data feeds.

The method further includes determining a plurality of metrics at least partially using the data feeds. As will be shown, this may include normalising and/or scaling the data feeds, or by combining multiple data feeds into a metric. In further examples, the metrics may be obtained using machine learning and/or regression techniques—and this is described herein.

A likely source of interference with the electromagnetic signals is then identified by, assessing relationships among the plurality of metrics. While this may be achieved in any suitable manner, typically this includes at least partially determining both qualitative and quantitative relationships among at least some of the metrics. In some instances, this includes at least partially determining causality in the relationships, and using the causality to identify the likely source of interference. Most typically, a machine learning algorithm is used to assess the relationships, and this may include a supervised and/or an unsupervised machine learning algorithm.

Beneficially, the above example allows a source of interference with an electromagnetic signal (such as a radio frequency signal) to be identified both in qualitative terms in relation to the potential source and the quantitative impact it has on the signal.

Further examples will now be described.

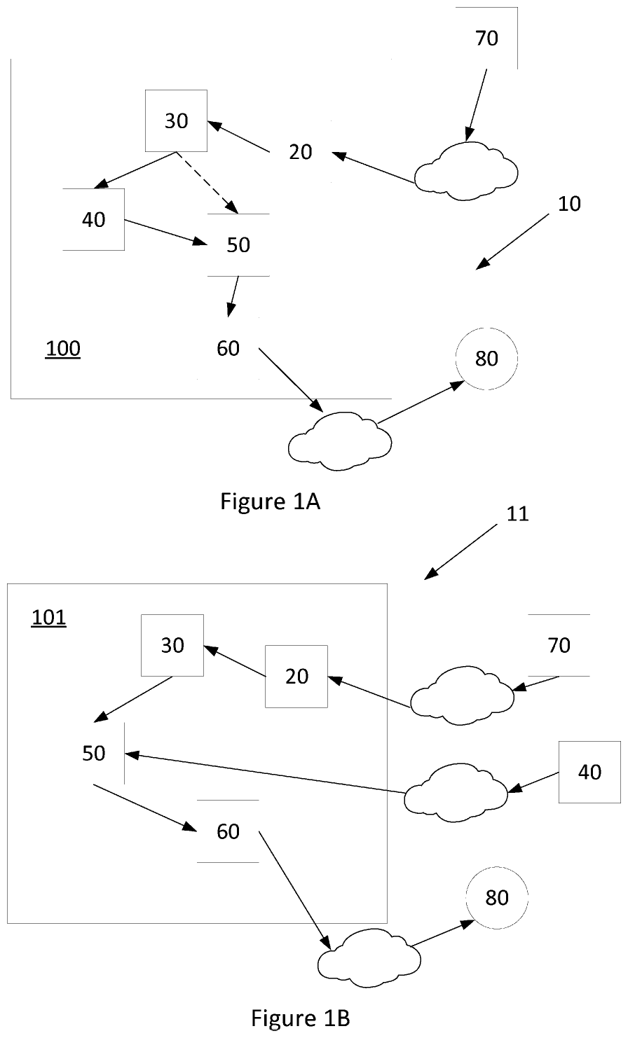

Referring to the FIG. 1A there is shown a system for assessment of aspects of one or more electromagnetic signals, the system generally indicated at 10. Electromagnetic signals may include any suitable signal, including any one or more of radio-frequency signals GPS signals, UHF signals, and the like.

FIG. 1A shows an electronic processing device and/or computer processor 100 which is configured to deploy statistical tools, using one or more numerical regression analyses, to identify and monitor relationships between performance metrics associated with one or more received electromagnetic signals. The computer processor 100 conducts this analysis by powering a machine learning regression engine 50 and assessment engine 60, with the support of a data engine 20, an optional scaling engine 30, a mapping engine 40, a data quality engine 70, and a display engine 80. As discussed below, while a signal processing device 100 is shown in FIGS. 1A and 1B. it will be appreciated that steps may be performed by multiple processing devices. Moreover, reference to an “engine” includes conceptual reference to a set of functional tasks/instructions, and thus the functionality provided by an “engine” may also be distributed among multiple processing devices (real and/or virtual).

In operation, the regression engine 50 is fed performance metrics from the scaling 30 and mapping engines 40 to identify stable relationships between metrics, while the assessment engine 60 checks whether any one or more of the relationships remain stable. If one or more of the relationships between metrics move beyond stable by a selected amount within a selected time period, the assessment engine 60 notifies a user of the discrepancy and informs them by display engine 80 which relationship has broken down, and by how much.

For example, when applied to the GPS and space weather metrics discussed herein, the assessment engine 60 can warn the user of the kind or kinds of interference to the GPS signal, and the quantum of interference from each source. In a further example, the system 10 may be applied to UHF-CB audio signals to determine interference type and quantity, and this will be described in further detail below. Indeed, any suitable electromagnetic signal and corresponding metrics may be monitored in accordance with the system 10 and method detailed herein.

For example, the method and/or system of the examples herein can determine whether an electromagnetic signal includes interference such as environmental stress (e.g. space and/or terrestrial radiation) and/or human-initiated intended or unintended signal noise. Beneficially, the system and method allow the type of interference to be detected in a quantitative method, and this will be discussed in more detail below.

For example, during testing, it was shown that these metrics have stable relationships; a. GPS position uncertainty and each of space weather, GPS satellite position, and local receiver condition.

b. space weather metrics and position/timing accuracies; and

c. local electronic interference and location accuracy.

Testing indicated that monitoring of these stable relationships facilitated;

a. Geomagnetic storm detection;

b. GPS accuracy service;

c. local electronic interference detection.

d. Signal interference, detection.

Thus, if one or more of these relationships changes over time, the change can be quantified and users notified, and the cause targeted.

In some examples, the assessment may include detecting and/or identifying signal interference and/or at least partially identifying one or more sources of interference of the electromagnetic signal. This can be particularly advantageous, as identifying the source can, for instance, inform an operator as to whether the interference is naturally occurring (e.g. environment) or the result of intentional or unintentional human intervention. This could in turn, for example, inform methods of rectifying or minimizing the interference, if possible.

In a further example, the system or method may be used to quantitatively predict and/or estimate the potential impact of an hypothesized source of interference on the electromagnetic signals. For instance, the system or method may be used to predict the impact of an hypothesized geomagnetic storm or interference source on a GPS signal or other electromagnetic signal. An impact assessment in this manner could include both quantitative and qualitative information about the hypothesised interference on the electromagnetic signal.

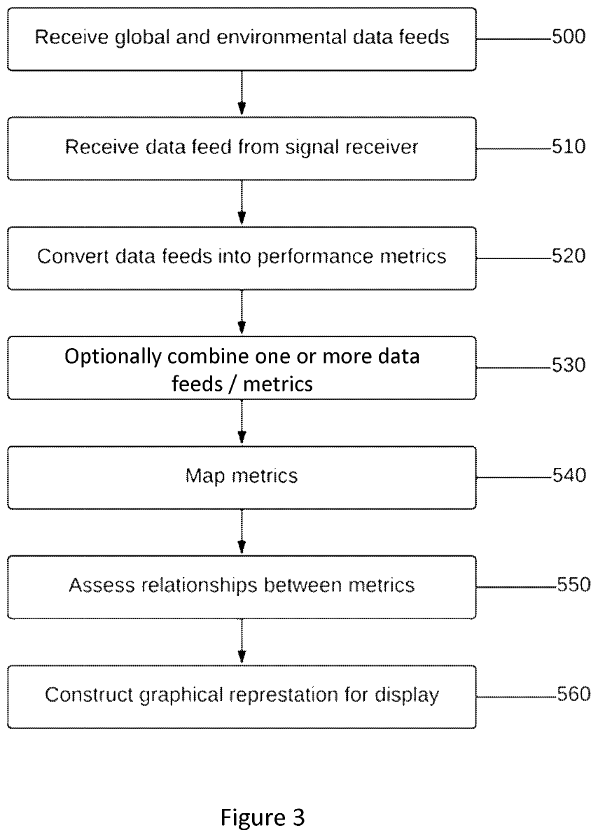

In any event, an example use of the system 10 will now be described with reference to FIG. 3. In this example the data engine 20 is configured to receive, retrieve, aggregate, filter and/or record data, depending on requirements, such as global and environmental data feeds at step 500. Data may be in the form of a time series data feed from various space weather sources around the world, including the NOAA Space Weather Prediction Center (USA), Bureau of Meteorology, one or more satellites, via the Internet or other network, via interface module 106 (discussed below), and the data from each source aggregated in data engine 20 to construct a coherent time-series data feed useful for processing in the regression engine 50.

The data engine 20 also optionally includes direct or networked links to sensors (not shown) which sense local environmental conditions and may include IR sensors, UV sensors, as well as at step 510 receiving data feeds from a signal receiver operable to receive the electromagnetic signal of interest, such as GPS signal sensors, UHF signal receivers, and the like. In some instances, at least some of the data feeds are at least partially indicative of observable characteristics of an electromagnetic signal receiver, such as an altitude, a height, a vibration, a temperature, frequency response, and power.

In some examples, data feeds may be at least partially generated using a processing device, as will be described in examples below. For example, one or more data feeds may be generated using synthetic radio generators, or the like.

The scaling engine 30 is configured to convert the data feeds into a metric at step 520. Typically, this includes normalises the metric, so as to facilitate comparison between other metrics. The scaling engine 30 is connected to and outputs to the mapping engine 40.

In one embodiment, the scaling engine 30 normalises a metric to an index or common unit and/or scale, so as to facilitate comparison between other metrics. In some examples, the scaling engine 30 may be configured to resolve the normalisations with one or more numerical techniques. In one example, the scaling engine 40 may be configured to conduct machine learning regressions to complete the normalisation.

In this regard, any suitable pre-processing of one or more of the data feeds into usable performance metrics may be performed, and this is typically dependent upon the feed, application, signal of interest, and the like. For instance, as will be discussed in further detail below, a performance metric may include a radio-frequency “signal type” which in one example is determined using radio frequency signals (the data feed) which are processed using a trained convolution neural network (CNN). Accordingly, other suitable metrics may be generated at least partially using one or more data feeds using appropriate statistical techniques.

In one instance, the scaling engine 30 is configured to output to the mapping engine 40 a metric with a unit value of between 0 and 1 for ease of comparison of metrics, depending on the numerical or algorithmic method selected for regression. In other embodiments, the unit value may be scaled in any appropriate manner for suitable comparison, such as between −1 and 1 or indeed any other suitable range, or other normalisation methods (such as having standard deviation set to the range [−1, 1] and five standard deviations being at [5, 5]), or the like. In some examples, however, data retrieved from the data engine 10 may not require normalisation or scaling. This may occur if data feeds output from the data engine are within a consistent range, have a comparable unit value, or the like.

Additionally or alternatively, the scaling engine 30 may be configured to select and merge one or more data feeds (or metrics) at step 530. While this step is indicated as occurring after the data feeds are converted to metrics (step 520), it will be appreciated that one or more data feeds may be combined prior to step 520 in other examples. Merging or combining one or more data feeds may be performed in any suitable man nor, such as using linear or non-linear signal processing methods or the like. Thus, normalisation may be performed prior to and/or after step 530.

Optionally, at step 530, one or more functional attributes may be quantified from interactions of one or more metrics—thus functional attributes may be quantified by merging one or more metrics. In turn, the functional attributes may be used to form and/or interpret the reference model (or System Map) in the foregoing steps. For example, a functional attribute such as “space weather” may be quantified using a subset of metrics which relate thereto, such as alpha hazards, electron hazards, proton hazards, and the like. In a further example, a functional attribute such as “GPS accuracy” may be quantified using a subset of metrics which relate thereto, such as GPS point distance, altitude, VDOP/HDOP, SNR, and the like. Thus, functional attributes may be useful in grouping related metrics to, for example, facilitate probabilistic inference scaling between model (or SM) properties, behaviours and individual metrics.

In any event, the mapping engine 40 is configured to facilitate the modelling of metric behaviours and relationships, e.g. with and without signal interference(s), for use in the regression engine 50, at step 540. Typically, mapping is performed in accordance with Systems of Systems model design concepts, as will be described further below. The mapping engine 40 is connected to, and outputs to, the regression engine 50.

Mapping the metrics (step 540) includes generating a reference model at least partially indicative of relationships among the one or more performance metrics. More typically, the reference model is indicative of the relationships among the metrics where it is generally known whether there is no interference and/or whether there are one or more sources of interferences, and optionally the nature of the sources. In some instances, the reference model includes a System Map (SM), which is typically generated in accordance with a Systems of Systems model design.

While mapping (step 540) is described in this example, in other examples generating a reference model may not be required, for instance, in an example using unsupervised machine learning. In this regard, metrics may be input into the regression engine 50 which uses an unsupervised machine learning algorithm to assess the relationships among the metrics to thereby identify a likely source of signal interference in the electromagnetic signal of interest.

In some embodiments, the reference model includes an at least partially trained machine learning model, and thus step 540 includes training the reference model. As will be appreciated, training a machine learning model may be performed in any suitable manner including online or offline. Thus, step 540 may be performed in any suitable manner, including online—where it may be performed during run-time in any suitable order (including after step 550). In this regard, the reference model could be updated during run-time as additional data feeds and metrics are determined.

In the preferred embodiment, mapping (step 540) includes training the reference model offline using the mapping engine 40. Accordingly, a mapping engine 40 (and an associated data engine 20 and scaling engine 30) may be operable outside of run-time and/or on a remote processing device. In this regard, while training the reference model may consume considerable computational power, this can be done prior to (or in parallel with) run-tine assessments. Thus, run-time assessments (e.g. step 550) could be performed utilising significantly less processing power, and in some instances, in real-time. In one example, the machine learning reference model may include one or more regressors, which are represented by matrices. Thus, they are compact when stored in memory, and require less computing power when performing predictions using the matrix regressors.

Moreover, typically offline training at step 540 includes the use of training data which in this example includes “training data feeds”—which are distinct from the data feeds determined when assessing relationships at run-time (see solid training and dotted lines in FIG. 1A, representing training and testing data feeds). In this regard, the training data feeds may be captured using the same or different sensors to those utilised when performing the run-time assessments at step 550, and are typically captured at a previous time. Accordingly, in some instances scaling (and optionally merging) metrics (steps 520 and 530) may be performed using different methods during training or run-time, depending upon sensor characteristics, and the like.

The machine learning reference model generated at step 540 may include any suitable model capable of modelling relationships among metrics, and more typically models both qualitative and quantitative relationships among the metrics. Most typically, the reference model is configured to model one or more states (in relation to signal interference) and causal relationship among metrics. For example, the states are indicative of the qualitative relationship, such that a state is indicative of a type of signal interference, or indicative that there is no signal interference. Additionally, causal relationships are indicative of the quantitative relationship among metrics.

In some examples, the reference model includes a feature extraction reference model indicative of the qualitative relationships, and a regression reference model indicative, of the quantitative relationships. In the preferred embodiment, the feature extraction reference model includes a pre-determined number of modes (or metric dusters) for a Gaussian Mixture Model (GMM), and the regression reference model Includes a regressor for each state which is indicative of a Dynamic Bayesian Network (DBN), and together these form a System Map (SM). The modes may be determined using a tuning algorithm, as described below. However other suitable models may be used. For example, the feature extraction reference model may include one or more neural networks, and the regression reference model may include one or more genetic algorithms, or the like.

Optionally, the number of modes (or metric clusters) is determined in accordance with a tuning algorithm. Tuning may be performed at any suitable time, such as prior to offline, training. In addition, the tuning algorithm may form part of the mapping engine 40 in some examples. For instance, the tuning algorithm may compare accuracy of the feature extraction model as the number of metric clusters is varied over a range. For instance, the output of the model may be compared to a predetermined reference as the number of clusters (also referred to as modes in relation to examples including GMMs) is varied. The number may be varied, for example, from 4 to 30, or any other suitable range. In performing the comparison between the model output and predetermined reference, any suitable distance function may be used, such as KL distance. This comparison provides an indication of the accuracy of the identification step at each of the number of clusters within the scanned range.

Thus, the number of metric clusters may be selected in accordance with the calculated accuracies. In one example, however, it may be desirable to additionally account for the computational requirements at higher numbers of metric clusters. Accordingly, in some instances the selected number of clusters may be a local minimum rather than a global minimum (which may be a higher cluster number). Hence, the number of modes may then be selected in accordance with any one or more of accuracy, computational requirements, and/or the like.

While online and offline learning are described above as distinct modes of learning, it will be appreciated that in other examples learning and/or generating the reference model may be performed using a combination of online and offline learning.

In any event, at step 550 the regression engine 50 and assessment engine 60 assess the relationships between metrics. In this regard, FIG. 1A is indicative of a system on a processing device 100 in which the regression engine 50 accepts input from the map ping engine 40 and optionally the scaling engine 30. In an online learning mode, in one instance the mapping engine 40 and regression engine 50 may interact to both assess the metric relationships and update the reference model using the same metrics. In another example, in an offline learning mode, the mapping engine 40 may generate the reference model using training data feeds (and consequently training metrics) with the reference model being output from the mapping engine 40 to the regression engine 50. At run-time, metrics obtained from run-time data feeds are input from the data engine 20 (optionally via the scaling engine 30) to the regression engine (dotted line) such that the relationships between these metrics at run-time can be assessed in the regression engine 50, using the reference model.

As described above, in a further example the reference model may be generated substantially offline, as shown in FIG. 1B. In this example, the system 11 includes a processing device 101 including a regression engine 50 that accepts as input, metrics from the data engine 20 (optionally via the scaling engine 30, as discussed above). In addition, the regression engine 50 determines the reference model, for instance, by retrieving the from a store (such as local or remote memory), or a remote processing device including a mapping engine 40.

In any event, in step 550 the regression engine 50 receives the reference model and the (scaled) metrics, and numerically analyses the normalised metrics by utilising statistical methods. The statistical methods are resolved by one or more machine, learning algorithms loaded into the regression engine 50, for example, from the mapping engine 40. The machine learning regression engine 50 is capable of resolving relationships using regression techniques. As discussed above, it has been identified in testing that suitable numerical techniques include nonlinear hybrid switching state space modelling. In one form, that includes Dynamic Bayesian Networks in combination with a feature extraction algorithm. The feature extraction algorithm is in the form of Gaussian Mixture Modelling, while the algorithm to do regression works in concert with ft. Neural networks are suitable to substitute for the GMM, and the DB N could be replaced with genetic algorithms depending on the circumstances.

So in use, the regression engine 50 is caused to undertake an identification step within the assessment step 550 which includes a clustering regression step wherein time steps in the data feeds are classified by conducting numerical regression. The regression engine is loaded with clustering regression algorithms which may be K-means clustering, Mean-shift clustering, DBSCAN, Expectation Maximisation (EM) by Gaussian Mixture Modelling, and/or Agglomerative Hierarchical clustering. This is a qualitative relationship identification step between a plurality of metrics.

in the preferred embodiment, the identification step is performed to match the metrics at the current timestep to the GMM using an EM algorithm and the predetermined number of modes. The output from the identification step is indicative of the state, namely, whether or not signal interference is occurring at that timestep and optionally the type, 188. The regression engine 50 is also caused, during the identification step, to conduct numerical relationship regression for one or more of the determined dusters, to identify the strength of the qualitative relationships, or causal nature, between a plurality of normalised metrics which had been identified in the clustering regression step. This is a quantitative relationship identification step.

In the preferred embodiment, typically the largest representative sample in the determined state the current timestep is selected for conducting the numerical relationship regression. In this regard, the regressor corresponding to the determined state is applied to the representative sample, with the output being indicative of a “measured” directed acyclic graph (DAG). This measured graph is indicative, of the causal relationship among metrics. That is, the DAG provides a representation indicative of which metrics have a causal relationship with others at that timestep, and hence the likely source (if any) of signal interference at that timestep.

In some examples, the relationship regression model analysed in the regression engine 50 utilises a plurality of metric clusters as inputs to the regression. In one embodiment the number of inputs is six, but it is to be understood that there may be models where three, four, five, seven, eight or any suitable number of clusters may be appropriate and stable.

The assessment engine 60 is fed data by the regression engine 50 and is configured to monitor and assess whether the relationship between any one or more resolved metrics is beyond acceptable limits. The assessment engine 60 in use monitors the relationship and whether any one or more stray beyond selected limits within a selected time, period.

The assessment engine 60 does this by storing the cluster regression and the relationship regression results for later analysis. The method includes the real-time use of the cluster regression and the relationship regression during real-time analysis of the electromagnetic signal. The assessment of signal relationships over time involves a comparison of stored or otherwise loaded cluster regression and relationship regression results, with new data received. The assessment step also includes conversion of new data into metrics. The assessment step additionally includes classification of a new metric by matching the metric to the relevant cluster.

The assessment engine 60 is caused to validate the results of the regression engine 50 by predicting the current timestep and comparing this with the stored or loaded relation ship regression result obtained via the regression engine 50. The predicted and measured timesteps are then compared, for example, using a distance function or algorithm.

In the preferred embodiment, the prediction for the current timestep is obtained by applying the regressor corresponding to the current state determined using the feature ex traction algorithm above, to the largest representative sample from the previous timestep.

Optionally, results of the assessment may be displayed via the display engine 80. The display may include any suitable audio or visual indicator indicative of the results, such as an indicator indicative of whether signal interference is occurring, the magnitude of the impact and/or the likely source of interference. In other examples, the results of the assessment may be used to display an indicator indicative of the likely impact of an hypothesised source of signal interference on an electromagnetic signal of interest. In some instances, the results of the assessment may be used to at least partially ameliorate the signal interference on the electromagnetic signal.

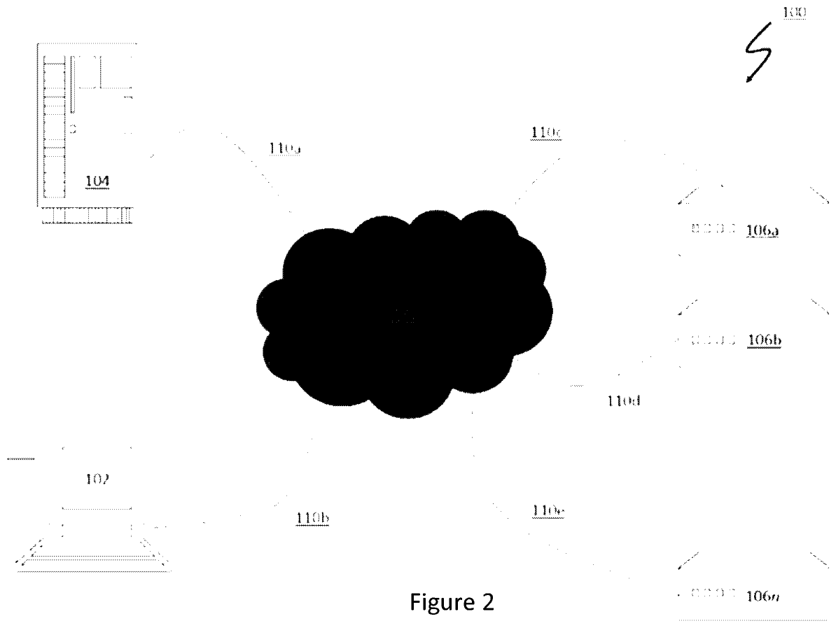

Functionally, these engines 20, 30, 40, 50 and 60 conduct their work within one or more computer processing systems, and, in a hope of enabling greater understanding of the technology, an example schematic of one can be seen in FIG. 2. It is to be understood that any one engine may not be disposed within one computer processing system but may be connected to any other engine by a network connection, as it is hoped may be understood by reading the discussion of the schematic system in FIG. 2. The whole of the system including all its engines may be hosted in a cloud environment, wherein each computing processing machine 100 may be implemented, potentially virtually.

It can be seen that FIG. 2 portrays a schematic diagram of an embodiment of an electronic system 100. The system 100 comprises several key components, including a user computer 102, an application server 104, interface modules 106, and a data network 108. The system 100 also includes various data links 110 that connect the user computer 102, the application server 104 and the interface modules 106 to the data network 108 so that data can be exchanged between the user computer 102, the application server 104 and the interface modules 106.

The user computer 102 may be any type of computing system and may include any sort of suitable computing device, including but not limited to a desktop computing system, a portable computing system such as a laptop, a smartphone, a tablet computing system, or any other type of computing system including a proprietary device.

For the purpose of clarity of understanding, the embodiment of the system 100 will be described with reference to an AMD, ARM or Intel-based computer such as those available from, for example, Lenovo, Dell or HR The user computer 102 has a hard disk (not shown in the diagrams) that contains a range of software and data. In particular, the software typically includes the Windows, Linux or OSX operating system. The storage device also contains a web browser application such as, although not limited to, Google Chrome.

The user computer 102 also comprises a keyboard, mouse and visual display device (monitor).

The application server 104 is in the form of an Internet-connected computer server and is an AMD, ARM or Intel based server or like server such as that available from IBM, Dell or HP or like manufacturer. The application server 104 has a hard or solid-state disk (not shown in the figures) that contains a range of software and data. In particular, the software on the hard or solid-state disk of the application server 104 includes the Linux operating system. In addition to providing the usual operating system functions, the Linux operating system also provides web server functionality. As described in more detail in subsequent paragraphs of this description, the web server functionality of the Linux operating system allows the user computer 102 to interact with the application server 104.

In addition to the Linux operating system software, the hard or solid state disk of the application server 104 is also loaded with a relational database and machine learning application, which includes a data engine 20, mapping engine 30, scaling engine 40. regression engine 50, assessment engine 60 quality engine 70 display engine 80, that the user of the user computer 102 can access, potentially via the interface modules 106. It is envisaged that in alternative embodiments of the system 100 different forms of the application server 104 can be used.

The interface modules 106 are not dissimilar to the application server 104 insofar as the interface modules 106 are capable of transmitting and receiving data. One or more of the interface modules 106 is connected to an aggregated data feed (not shown in FIG. 2) that is partially or wholly monitored and/or controlled by the interface modules 106. 04.

The data network 108 is in the form of an open TCP/1P based packet network and in this embodiment of the system 100 the data network 108 is equivalent to the protocols and systems utilised on the Internet. The primary purpose of the data network 108 is to allow the user computer 102, the application server 104 and the modules 106 to exchange data with each other. To further facilitate the exchange of data between the user computer 102, the application server 104 and the modules 106, each of those components are in data communication with the data network 108 by virtue of the data links 110. The data links 110 are in the form of broadband connections. In alternative embodiments of the system 100 different forms of the data network 108 can be used.

Five initial example tests were conducted on the preferred embodiment (including system map generated using GMM and DBN). In Examples 1 to 5, an initial system map was modelling using data from a GPS tracker and a data logger, and space weather data.

Test conditions are outlined in the table below.

| Test | Condition | Use Case Hypothesis |
|---|---|---|
| Preliminary | Static GPS unit outdoors + | Geomagnetic Storm |
| | 50% space weather | detection |
| Static Station | Static GPS indoors + 75% | GPS Accuracy Service |
| | space weather metrics | MVP |
| Static | Static GPS indoors with | n/a prelim test |
| Perturbed | magnetic perturbation | |
| Static | Static GPS indoors with | GPS local interference |
| perturbed2 | signal perturbation | Detector |
| Metric | Removing local GPS | GPS Targeting Support |
| removals | maintenance metrics | Tool |

Each test has scenarios designed to be ‘day-to-day’ environmental conditions as well as increasing perturbations to GPS in a controlled fashion.

### EXAMPLE 1

A test was conducted to assess whether an efficient geomagnetic storm detector could be constructed using the processing engines and sensors described herein.

The test consisted of multiple-day datasets. A training dataset was selected to train the System Model and then test data sets were selected to validate the quality of the model on new data. Earner datasets lasted 4-12 hours in duration and sought to capture day/night cycles and space weather dynamics in the statistics. With very short test sets the inventors obtained spot-checks on data volumes which was useful to converge a solution. More advanced tests used a single day of data to train and then a different full day for the test set.

The data engines 20 polled a full data packet (all sensors and GPS) every 1 or 5 seconds, with space weather and other environmental data filled in at the rates available.

The aim was to determine whether stable relationships between metrics could be identified to yield useful information. The method utilised was to engage the regression engine 50 to train a minimal System Map on it, so as to evaluate convergence, accuracy, and seek connections between the GPS accuracy and space weather conditions in the Map.

The following metrics were used;

met_21—Local magnetic field

met_23—Electron SPWX Hazard

met_24—Proton SPWX Hazard

met_26—Alpha SPS Hazard

met_28—GPS Constellation Strength

met_30—HDOP

met_33—Data Timeliness

met_34—GPS Position Uncertainty

met_36—GPS Altitude Uncertainty

met_43—Local GPS IR Dose

met_41—Local GPS UV Dose

Data was collected using a GPS data engine 20 located at a remote NSW region. Approximately 9600 time steps were gathered representing a 1 Hz rate. Space weather metrics were gathered using data engine 20 depending on availability ranging from 1-minute to 2-seconds per tic. Data merging in the data engine 20 was conducted in Python. Missing data was represented as zero performance when it occurred in the space segment. The GPS was stationary. A model was trained in the regression engine 50 and tuned to seven Gaussian Mixture Model (GMM) mixtures (states) which is the local optimal for the dataset.

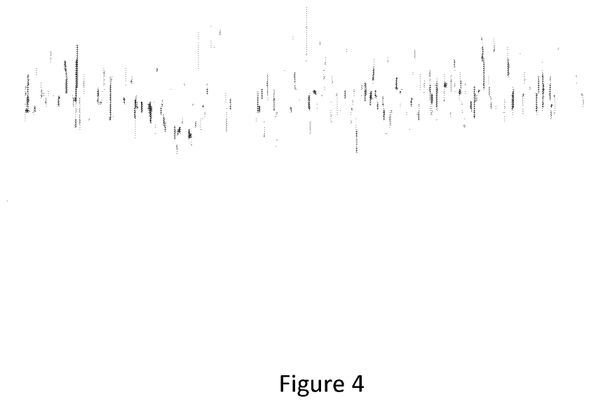

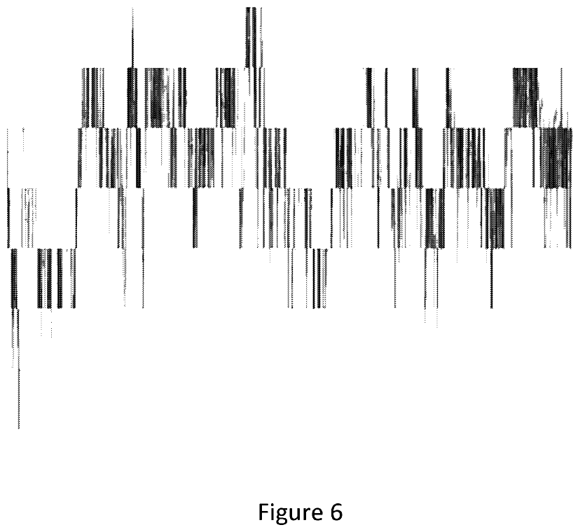

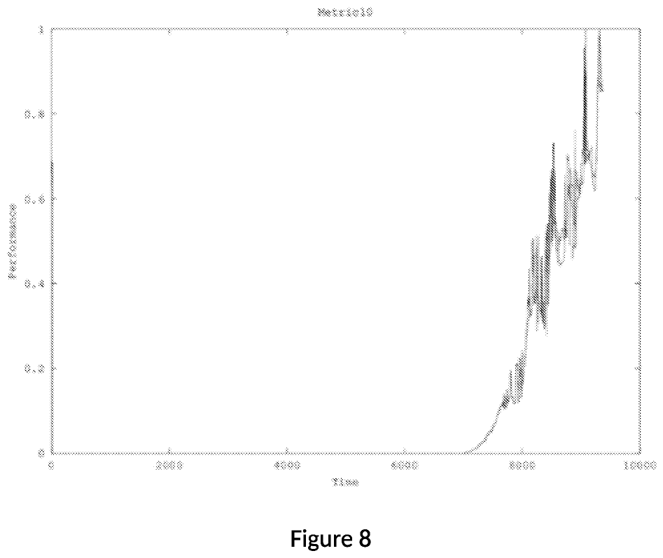

Snapshots of the results are shown in the FIGS. 4 to 8. Blue lines represent “truth” data while red lines are estimates output from the SM model. The closer these lines are together the more accurate/faith an operator can have in the causal model. FIGS. 4 to 8 are representative samples of the model's performance to date.

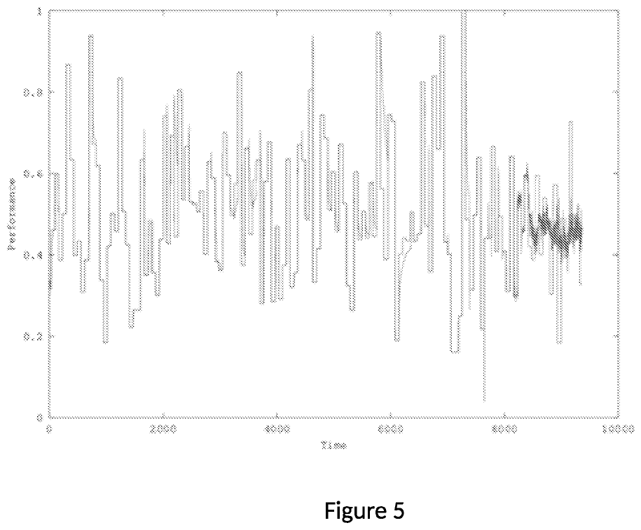

FIG. 4 shows that electronic SPWX was relatively calm with minor burst occurring from time t=3000 to 3500. FIG. 5 shows that alpha SPWX was also very calm. Twilight occurs at approximately time=7000 and heats up with sunrise at about 8400. Daytime warms the ionosphere which expands with Earth's magnetic field.

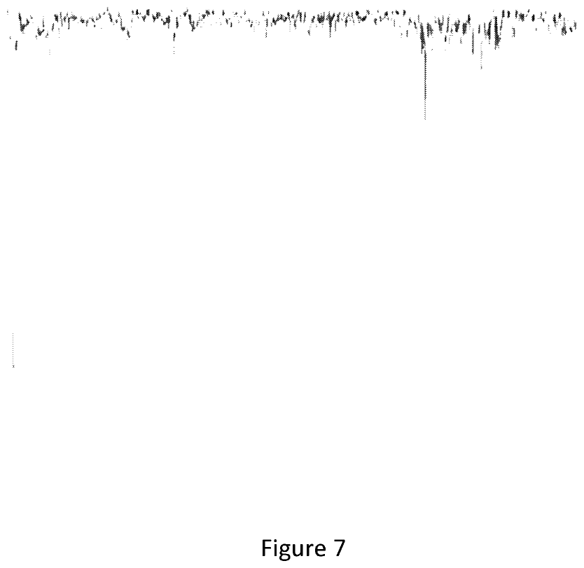

In FIG. 7, GPS position accuracy includes a drop in accuracy at the start of the test due to acquisition of signal when first turning on the unit.

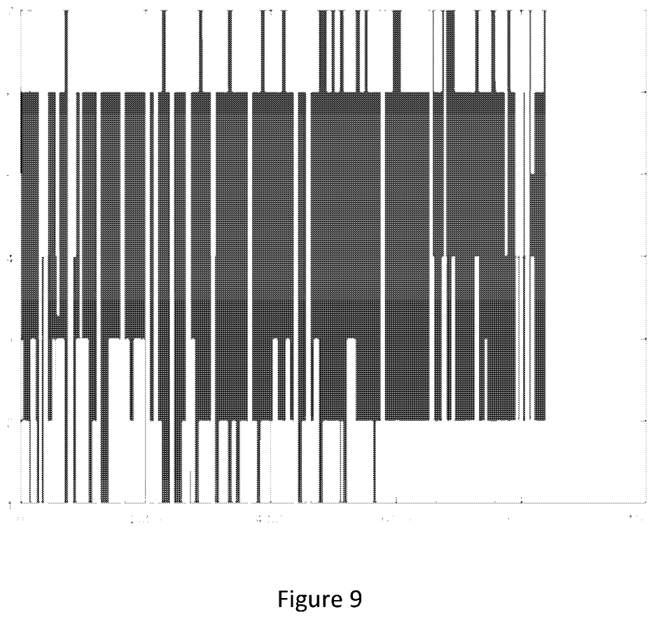

FIG. 9 shows the state number used at each time step in the model. Rapid switching relies on the GMM while low switching relies on the DBN. The GMM regressions typically always assume full connectivity in the model, while the DBN attempts to approximate causality. States 6 and 2 did not converge the DBN, so are entirely dominated by the GMM.

Analysis of mod& accuracy shows clear convergence fitting the SM to current data. Day/night cycle is represented well up until time t=8500 (FIG. 9), although the SM is still accurately representing the mean. Further investigation showed that prior to this time the SM relied heavily on the GMM for a solution, which is very good at handling rapidly switching states (quick swapping between high and low relationships).

Results

Examining the System Map regression terms more closely shows the following stable relationships:

GPS Position Uncertainty with space weather, GPS satellite strength and local UV conditions.

GPS Altitude Uncertainty with space weather, GPS satellite strength and local R conditions

Conducting a sense check, we are encouraged that these relationships are correct: GPS position accuracy improves with a greater number of nearby satellites and degrades with worse space weather and some local UV/IR measurements. Most importantly the results converge with a reasonably small dataset and minimum metric space and handle data which occurs shortly outside of the initial training set. Further testing is underway to determine the strength of the model and generality, as well as adding more metrics.

The graphs in FIGS. 4 to 18 show that the model with real-time data settled in and converged to provide stable results similar to the training data.

### EXAMPLE 2

The aim was to determine whether the regression engine 50 could resolve to find relationships between space weather, local GPS condition, and GPS accuracy in long duration indoor nominal conditions. The method adds to Example 1 with additional metrics for space weather (75% of available data streams) which were captured using space weather satellites. A 3-day continuous data logging was conducted indoors with no perturbations. The training set used 100 k time-steps to train an SM and 50 k time-steps to evaluate the accuracy.

The following metrics were used: met_14—Signal/Noise ratio

met_19—Magnetic Complexity (space)

met_20—Magnetic Strength (space)

met_21—Local magnetic field (at GPS)

met_23—Electron SPWX Hazard

met_24—Proton SPWX Hazard

met_25—X-lay SPWX Hazard

met_26—Alpha SPWX Hazard

met_28—GPS Constellation Strength

met_29—PDOP

met_30—HDOP

met_31—VDOP

met_33—Data Timeliness

met_34—GPS Position Uncertainty

met_36—GPS Altitude Uncertainty

met_39—GPS

met_40—Local GPS IR Dose

initial tests showed the GMM had difficulty converging with at least UV dose. Individual metrics can cause a GMM to fail converging in certain cases where the metrics cause too many states to seem too similar. Since UV dose is supplementary a was removed in tuning. The GMM converges with six states but larger number of states do not converge.

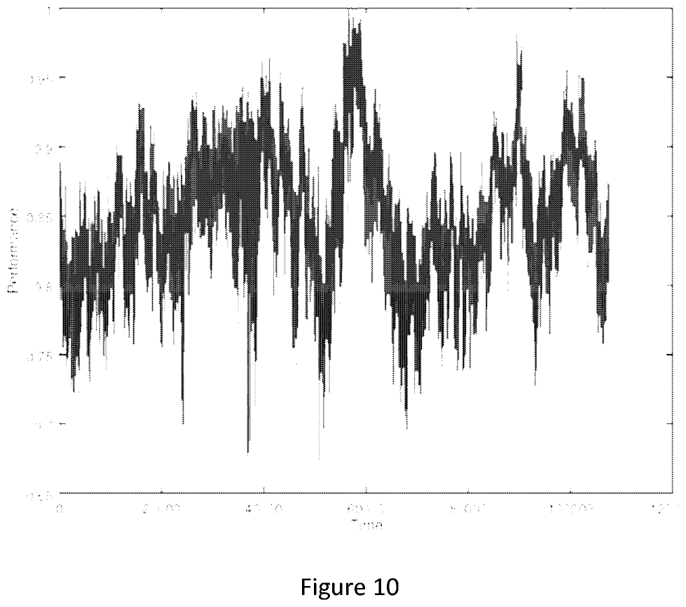

For the GMM of six mixtures the resulting model trained accurately with >95% fit. The figures are the performance for critical metrics below. FIGS. 10 to 12 are also representative of the rest of the model's performance during Test 2.

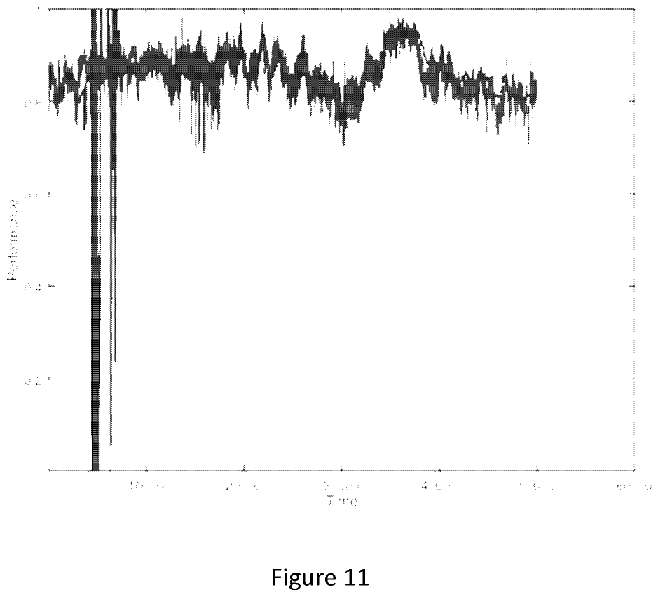

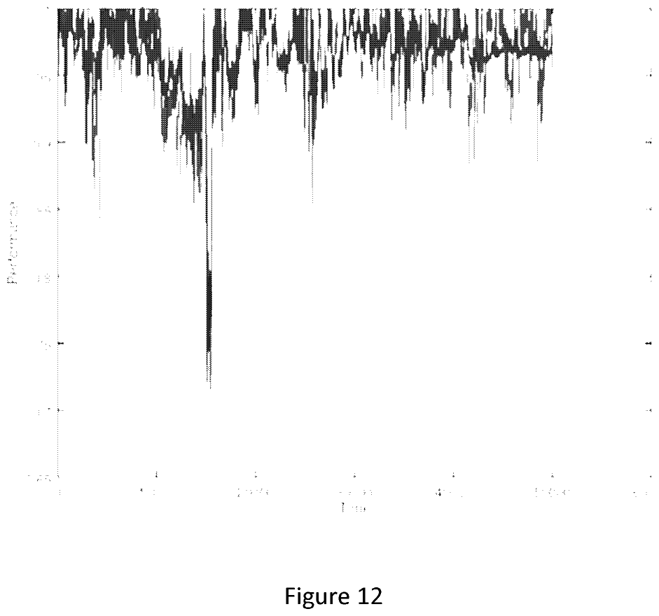

FIG. 10 shows SNR performance (metric 14) has a very high fit during training, and FIG. 11 shows that SNR performance keeps strong accuracy after training (with some anomalies at timestep t=5 k). FIG. 12 shows that metric 34, position uncertainty, had very high accuracy in run time with some reduced accuracy after t=35000.

The results show highly accurate model training. The SM also maintains accuracy in conditions after the training period, albeit with several notable anomalies indicating that one state in the GMM did not completely converge.

Relationships were found in the DB N between space weather metrics and position/timing accuracies. R also showed relationships between the SNR and number of satellites in view. This validates the Use Case for a GPS Accuracy service which can independently account for space weather from DOP.

### EXAMPLE 3

The aim of the test was to demonstrate a basic capability to detect effects on GPS accuracy resulting from non-natural perturbations. Two methods were attempted-magnetic perturbation and spark gap generation.

Magnetic fields would not have an effect on the signal itself however it was hypothesised that a solid-state magnet waved near the computer processor 100 may perturb the GPS receiver hardware, possibly affecting the location accuracy. However, no perturbations were detected, and while the approach may bear fruit with a more formal testing and stronger magnets it was deemed to be less relevant to signal diagnostics in practice.

The spark gap generator described herein below generates very short-range signal noise in short 10-20 second, high voltage bursts, spread over six minutes. Short duration was to ensure the prototype spark gap generator did not overheat. The orientation of the coil was also adjusted to test maximum effect on field strength. The field strength was strong enough to crash the computer processor 100 in certain orientations, where possible the system was re-started to continue data logging.

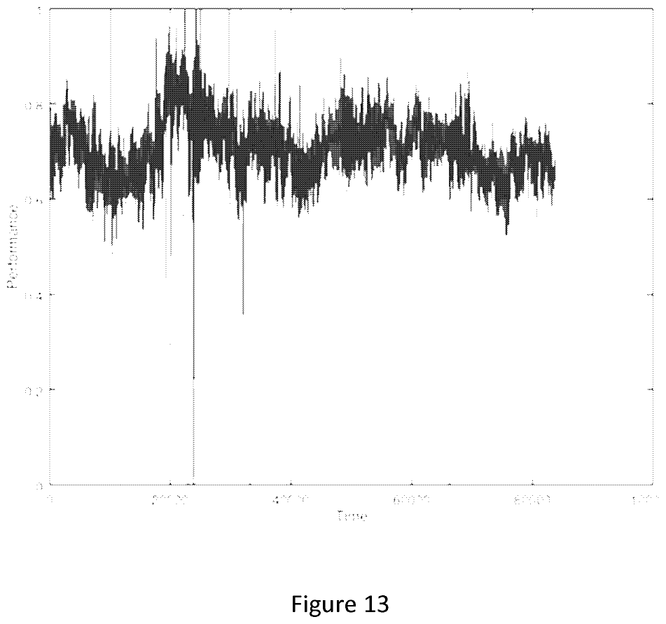

Training had similar behaviours and fits as in test 2. The FIGS. 13-18 show behaviour of the model for tracking SNR, local magnetic field at the GPS receiver, and position ac curacy.

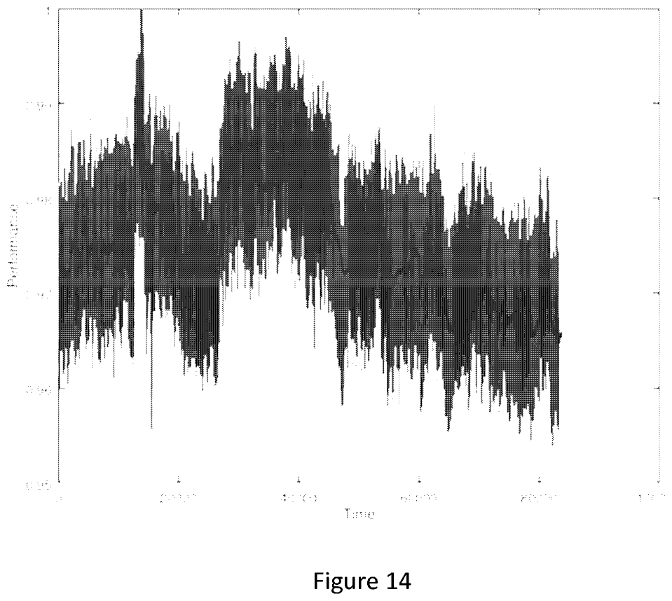

FIG. 13 shows that SNR performance modelled accurately, albeit with a small number of false positives related to GPS dropouts in the training set (nine false positives out of 90k timesteps). FIG. 14 shows local magnetic field with clear model convergence and minor perturbations from the spark gap generator near time t=18 k.

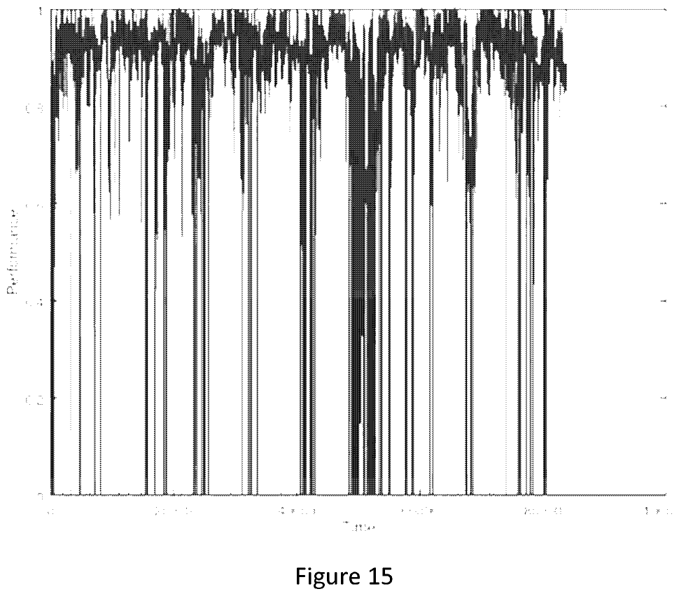

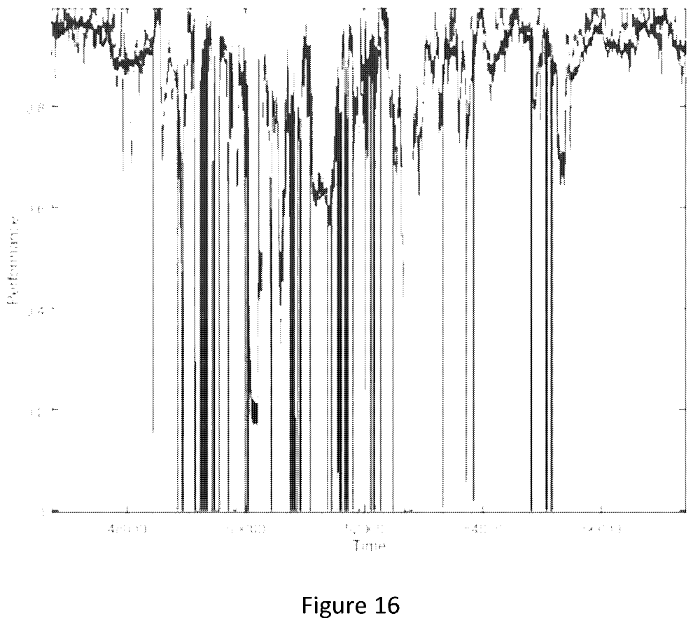

FIGS. 15 and 16 show metric 34 (position accuracy). Large spikes are also accurate, showing how that many GPS drop outs occurred and were modelled accurately. At higher resolution (FIG. 16) some loss of accuracy near 48 k represents a DBN that has not completely converged but still trends the mean.

Relationships were found in the DBN between position/timing and SNR as well as local magnetic field. It also showed relationships between the SNR and number of satellites in view. This shows evidence of ability in using the SM as an interference detector by tracking the relationship between SNR, space weather, and DOPs.

### EXAMPLE 4

The test included the current from the spark gap generator which represents interference Power,

Based on results from Example 3, additional shielding was added to the computer 100 for better survivability. Fewer processor re-starts were noted. Data was collected for seven days in an attempt to more broadly capture space weather events as the period was relatively calm. The sixth day of the dataset (approx time t=50 k) captured perturbations with very clear performance response to the location accuracy. The model was tested to 12 mixtures with an 11 mixture GMM showing a local optimal.

Results showed detection of interference events with clear GMM identification of state. Due to the nature of the test setup and sensitivity of the sensors the SM detected strong relationships between the spark gap action, and anything affected by the resulting strong magnetic field. The current reader on the spark gap generator was also affected by other local magnetic (non-sparking) events. However, the SM was able to separate these events from the actual spark gap perturbation. Spark gap current showed very strong correlations to on-board temperature sensors as well as sharp changes in PDOP represented in the SM. Relationships were also found with position accuracy, magnetic field, and SNR during the spark gap event.

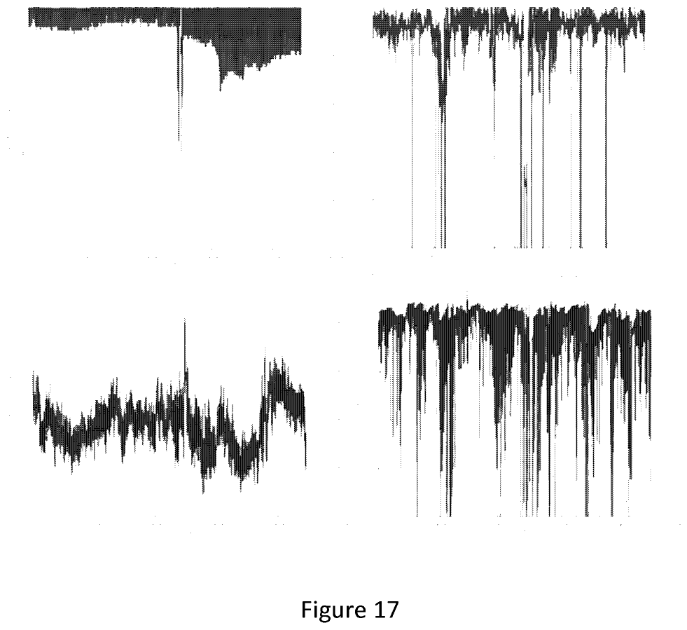

In particular, FIG. 17 includes snapshots of (upper left) M1 current on the spark gap. (upper right) Metric 34 position accuracy, (lower left) M2 SNR, (lower right) Metric 10 local magnetic field. The spark gap event is visible at t=50 k, and while this is a very high noise environment the SM shows a confident fit.

The GMM detected the perturbation in an identical fashion as shown in Example 5, conclusively identifying the event as belonging to a single mixture within the GMM model.

### EXAMPLE 5

The GMM detected the perturbation in an identical fashion as shown in Example 5, conclusively identifying similar events as belonging to (representable by) a single GMM mixture within the model.

This example is a response mitigating technical risks to understand performance of the SM when space weather data is in poor supply. Space weather data gaps occur because Australia relies on secondary sources from the US and EU. There are occasional gaps in coverage and some satellites have only partial coverage over regional South East Asia.

The test used the same dataset from EXAMPLE #4. Space weather data streams were set as constant value effectively removing them from the model training search priority. Larger numbers of mixtures showed to be more accurate and we stopped tuning with twelve mixtures.

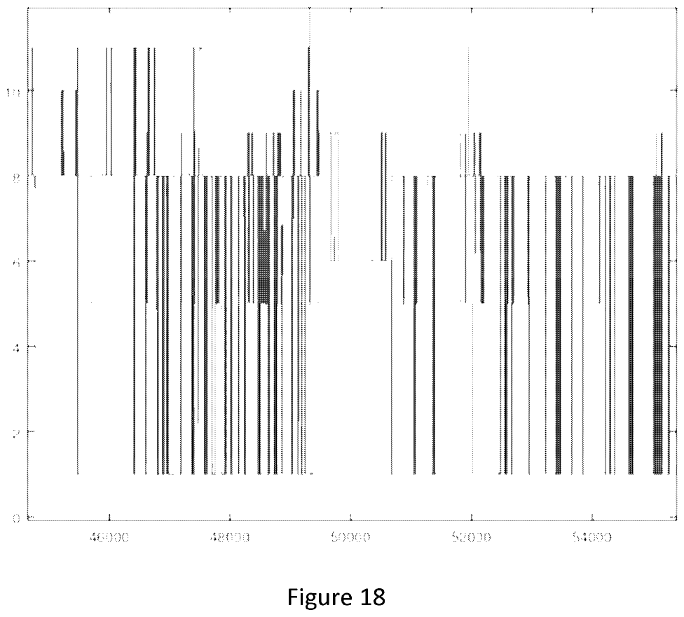

The state vector (FIG. 18) shows a clear GMM mixture identifying a period of degraded accuracy during spark gap generation (see mode 6 at t=50 k). The SM showed specific relationships between the SNR and position accuracy but was otherwise sparse. Large number of mixtures in the GMM means there are fewer time steps for the DBN step to train, so this result is expected.

The result is if space weather is unavailable intentionally overfitting to the GMM results in a direct use interference detector. You won't know why/how interference occurs from the model directly but there are mitigation strategies using multiple models for key frequencies of interest.

### EXAMPLE 6

Further field experiments were conducted, and these will now be described.

In particular, environmental and spectrum data of electronic signal interference degradation was conducted over 4 days within six-hour windows each, and included moving targets, dynamic environments, and active interference. Space weather data was collected in-situ. Testing was conducted within the first 3 days, and the 4th Day reserved for validation of datasets gathered and additional off-site work. Local GPS/Environmental dataloggers gathered per-second tick data which was been used to build primary metrics and regressions from training. Raw in-phase/quadrature (IQ) signal data was captured and examined to assist in constructing realistic synthetic representations for use in model creation and Neural Network training,

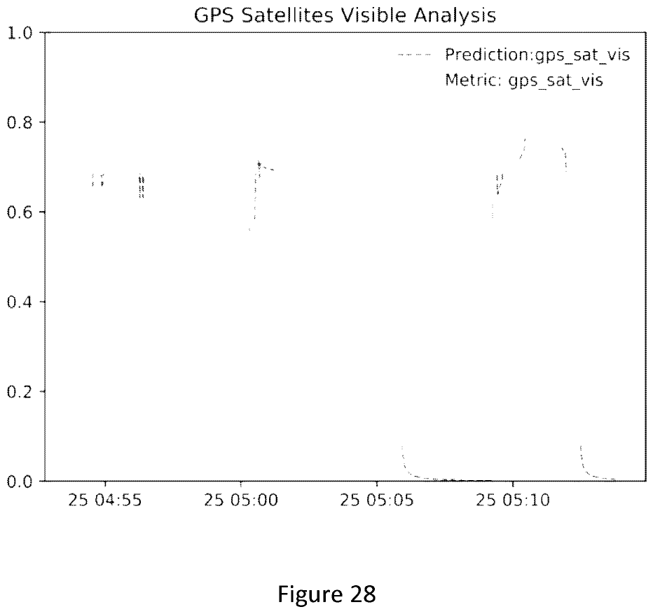

Signal interference in this example occurs in a controlled sporadic fashion, with most ranging from 30 seconds to 5 minutes in duration. For example, FIG. 28 shows results obtained in this Example relating to a satellite visibility metric. As will be appreciated, a GPS signal can be influenced by the position and visibility of corresponding satellites. Accordingly, the number of satellites which are visible can be an indicator of GPS signal duality, GPS constellation arrangement, or the like. In this example, signal interference events reduce the displayed metric to zero, indicating visibility of the satellite is lost.

Reid loggers capture at a rate of 1 Hz current environmental and GPS data as available from off-the-shelf sensors. Each logger contained a unique GPS chipset to provide variability to performance under adversarial conditions. Packet output is to the NMEA standard, the default international GPS message format. Activation times and durations were recorded for construction of metrics and checking of model outputs.

Data collected during this experiment was utilized to create and test a GPS System Map Further detail is provided below.

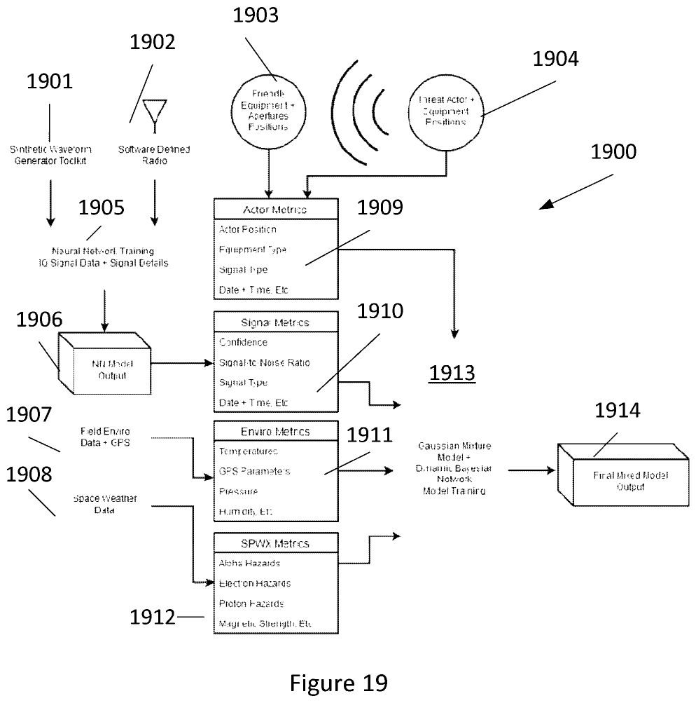

The System Map 1914 was generated in accordance with the data pipeline 1900 shown generally in FIG. 19. In particular Systems Maps may be generated in accordance with any one or more of the metrics listed, as will be discussed in specific examples be low.

The pipeline 1900 includes a neural network model 1906 which estimates signal-related metrics 1910, which may be derived from signal data such as signal type, confidence (of estimate), signal-to-noise ratio, and the like. The model 1906 is trained at 1905 using a combination of synthetic and real-world signals from a synthetic waveform generator toolkit 1901 and software defined radio (SDR) 1902, respectively. Optionally, a real-time targeted radio dataset generator may be used, and this will be discussed in more detail below. An example of the model 1906 and corresponding training 1905 will be detailed further below.

Field environmental data and GPS signals are detected using one or more data loggers at 1907. Environmental metrics 1911 may be formed from the signals detected at 1907 including temperature, GPS parameters, pressure, humidity, and the like.

Space weather data is captured at 1908, and SPWX 1912 metrics relating to radiation, magnetic field and the like may be determined from data such as alpha hazards, electron hazards, proton hazards, magnetic field strength, etc.

Actor metrics 1909 may also be utilized in the pipeline 1900 for example, as determined in accordance with friendly equipment and/or aperture positions 1903 and/or threat actor equipment positions 1904. Actor metrics 1909 may therefore be generated using actor position, equipment type, signal type, date, time and/or the like.

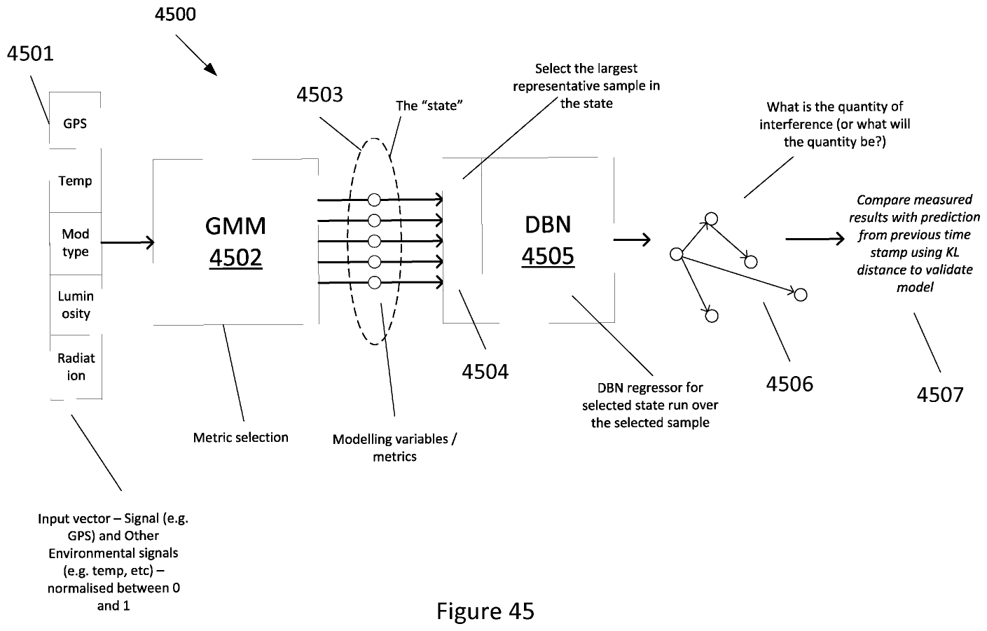

As described in the above examples, one or more of the described metrics 1909, 1910, 1911 1912, may be determined during training of a GMM and DBN model at 1913. 256. An example of training and using a GMM and DBN 4500 will now be described with reference to FIG. 45, which shows the process at each timestep.

As described above, the GPS signal (or other signal of interest, such as UHFN) and other environmental, cosmic or actor-related data, such as temperature, modulation type, luminosity, and the like is input into a Gaussian Mixture Mod& (GMM) 4502. In this regard, the data feeds may be normalized and/or filtered in any suitable manner for input into the GMM 4502.

The GMM is used to duster the data feeds into a predetermined number of modes. The number of modes is selected in accordance with the data and application, and further details are provided below. Clustering in the GMM is performed using the expectation maximization (EM) algorithm. As the EM algorithm is known in the art, it will not be described in further detail here.

Output of the GMM is a plurality of metrics which qualitatively provide the “state” of the system at the current timestep. The state could be indicative of the type of signal interference, for example, such as directional signal interference actuator, geomagnetic storm or the like.

At 4504, the largest representative sample in the state is selected for input to the DBN 4505. DBNs are generated for each state. During the current timestep, the DBN regressor for the selected state is used together with results from the previous timestep to predict a “prediction” directed acyclic graph (DAG)—namely, a predicted relationship among the determined metrics. In addition, the largest representative sample in the state 4504 from the current timestep, and the DBN regressor for the selected state, are used to determine a “measured” directed acyclic graph (DAG) 4506.

The predicted and measured DAGs are compared at 4507, for example using a distance function such as KL distance. Should the KL distance between the predicted and measured DAGs diverge beyond, for example, a pre-determined threshold, this may indicate, a model invalidity, relationship breakdown or the like.

The DBN regressors are typically represented in matrix form, with the number of rows and columns being the same as the number of metrics. Hence, for example, the relationship between two metrics x and y is at the regressor matrix at (x, y). Advantageously, when using trained regressors offline, the model is particularly portable as the matrix is compact and updating or calculating the DAG using the DBN regressor and a previous or current timestep is particularly computationally efficient.

Further features of the pipeline 1900 will now be described in more detail.

Synthetic Waveform Generator 1901

The synthetic waveform generator 1901 is able to generate a wide range of synthetic datasets with different modulation types and features, thus allowing a wider range of experimentation when field collection is not possible. This is particularly advantageous in some instances, for example, in creating appropriate training datasets to train a neural network, such as at 1905.

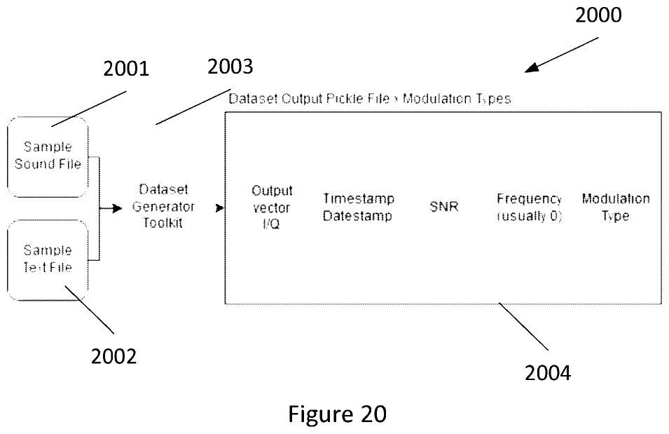

An example of a synthetic waveform generator will now be described with reference to FIG. 20. In this example, signal datasets in this generator are typically generated using large word-based dataset(s) 2002 (e.g. complete works of William Shakespeare) and/or a large audio file(s) 2001 (e.g. any copyright-free music or audio samples).

The dataset generator toolkit 2003 accepts the one or more inputs 2001, 2002, and generates the resultant signal in accordance with one or more parameters 2004, such as output vector I/Q, date/timestamp, SNR frequency and modulation type. While this may be achieved in any suitable manner, in this example signals are generated using methods descried in “Radio Machine Learning Dataset Generation with GNU Radio” (O'Shea and West (2016) In Proc of 6^{th} GNU Radio Conference).

Generated signals may include sequential and non-sequential data. Generated signal modulation types may include, for example, BPSK QPSK, 8PSK, PAM4, QAM16, QAM64, GFSK, CPFSK, FM, AM, AM-SSB, RADAR, POCSAG, RTTY, and the like.

Noise may be incorporated, including sample batches from −20 dB SNR to +20 dB SNR in increments of 2 dB. In addition, generated signals typically include random noise/spurs to help them resemble real signals.

In addition, intentional interference signal profiles may optionally be created interference which can be transmitted with SDR hardware 1902 in real-time or used to train algorithms on specific attack types.

Beneficially, the synthetic waveform generator 1901 provides pseudo-randomised signal data which can be used to train the CNN 1905 directly on how to identify various types of modulation, signal characteristics and more without requiring continuous access to real data. This can be particularly useful in scenarios where certain types of modulation/interferences cannot be readily sampled.

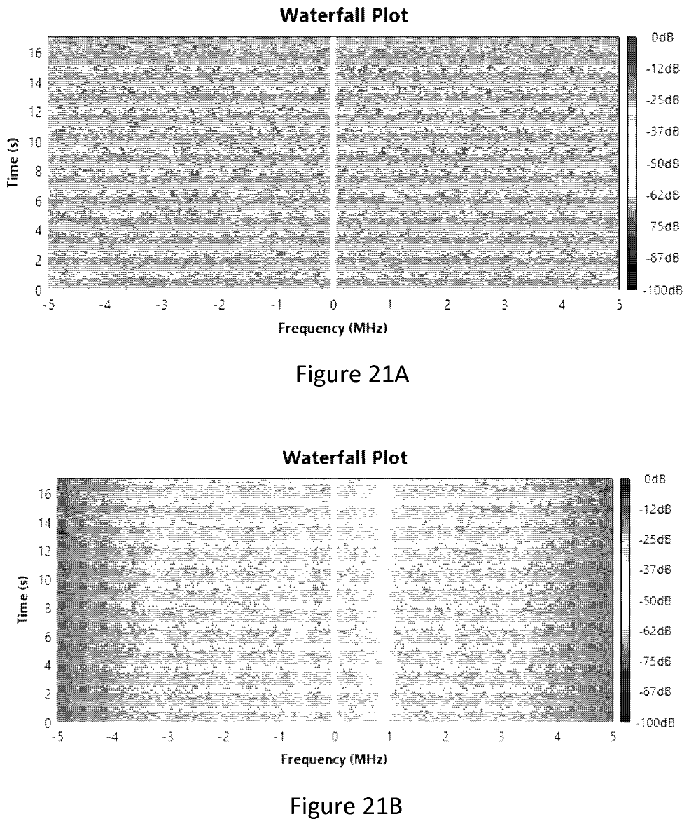

FIG. 21A is a waterfall plot of a synthetic waveform generated using the generator 1901. The synthetic signal includes a Gaussian noise frequency-interference event. FIG. 21B provides a comparative real-world signal of a GPS interference event, as recorded during the experiments of Example 6. As shown, the Gaussian noise generated is present in both FIGS. 21A and 21B at OMHz. The band at 1 MHz in the real signal (FIG. 21B) is the carrier frequency offset resulting from non-ideal real-world conditions associated with the transmitter and receiver antenna. Also, note that the dark bands at +/−5 MHz in the real-world results (FIG. 21B) are also an artefact of the limitations of the real-world antenna to receive signals at these frequencies.

Realtime Targeted Radio Dataset Generator

A SDR dataset generator may optionally be used to allow creation of datasets using SDR hardware 1902, allowing a user to tune into a real signal, and sample it for use in model training at 1905. In addition, once a real signal is gathered, it can be subjected to multiple signal-processing or filtering pipelines and then saved as a dataset.

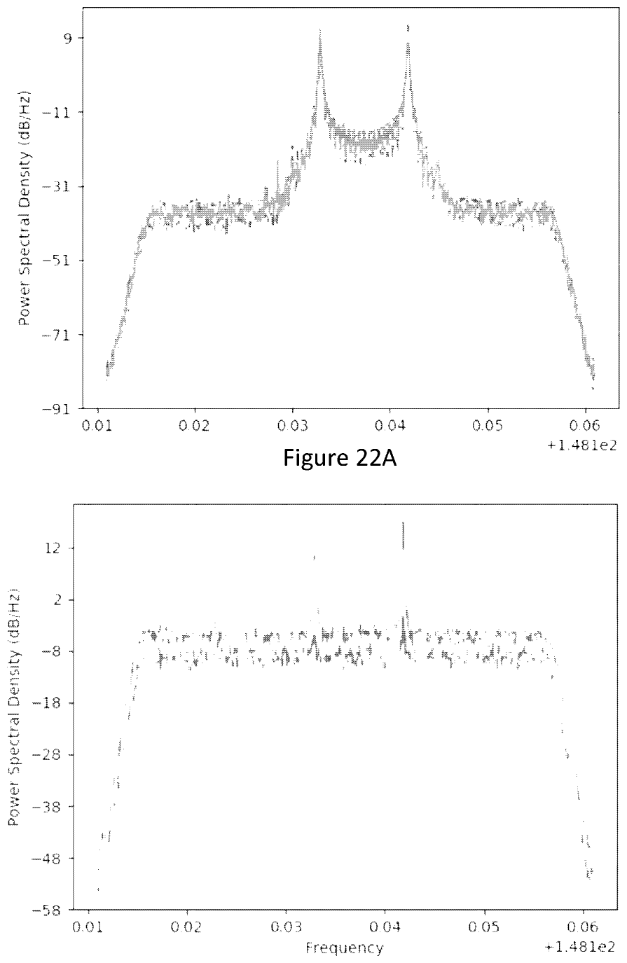

An example of this is introducing random noise to each sample gathered, resembling a noise-interference event, such as shown in FIGS. 22A and 22B. In this example, the power spectral density of a recorded POCSAG signal sample is shown in FIG. 22A, and a power spectral density of the same signal source with injected Gaussian noise is shown in FIG. 22B. Sharp edge boundaries result from decimation and general SDR function which are removed in processing

In this example, the generator typically generates datasets by parsing IQ data from a software-defined radio (SDR) 1902 at user-predefined frequencies. Additionally, realtime additive white Gaussian noise injection is possible in order to output a dataset of real data with synthetic noise-interference effects.

Polling interval rates are customisable dependent on storage constraints and processing requirements. Frequency ranges may vary in accordance with SDR software, for example, for higher sensitivity hardware ranges may include 50 Mhz-1 6 Ghz, and lower sensitivity hardware ranges may include 1 Mhz-6 Ghz.

Advantageously, the generator creates datasets in the same format as the synthetic dataset generator 1901, using real signals sampled in real time with SDR hardware 1902. A user may define known signals and theft frequency, and the tool will tune into and sample required frequencies. This output dataset is typically automatically stored in correct, labelled formats ready for training in for the CNN 1905.

Convolution Neural Network (CNN) SDR Spectrum Trainer 1905

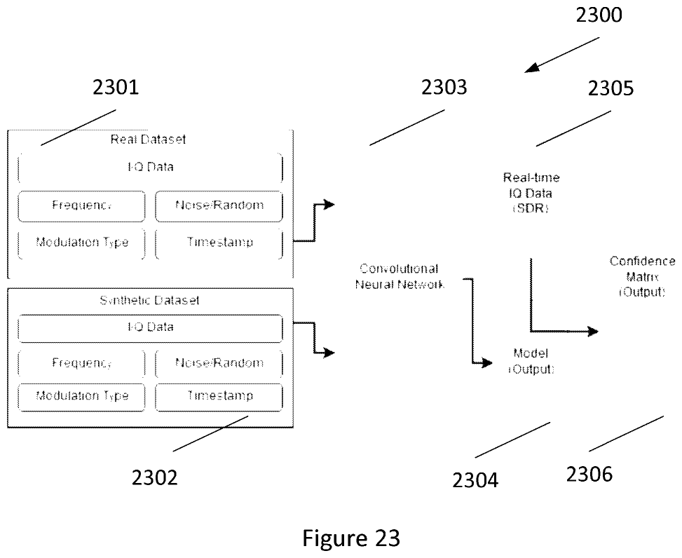

The CNN is trained at 1905 using real and synthetic datasets. FIG. 23 is a schematic diagram of dataflow in one example of CNN training 1905, its resultant output and potential use. In this regard, the CNN—once trained—classifies the modulation type of input signals which can be particularly useful in at least partially determining metrics. Any suitable method of modulation recognition may be used, including methods described in O'Shea et al. (2016) “Convolutional Radio Modulation Recognition Networks”, In Proc EANN16: Engineering Applications of Neural Networks, pp 213-226.

In this example, synthetic dataset(s) 2302 and real dataset(s) 2301 are used in CNN training. As discussed above, these datasets 2301 2302 are typically generated using the generators 1901 and the real-time targeted radio dataset generator, and include IQ data of a pre-determined frequency, noise, modulation type and/or timestamp. The synthetic signal may include simulated interference or Gaussian noise, for example. Once the CNN 2303 is trained, the output model 2304 may be used to accept real-time IQ data 2305 (for example, from an SDR 1902) as input, and output a confusion matrix 2306 which is indicative of a discrete model of the input signal's modulation type.

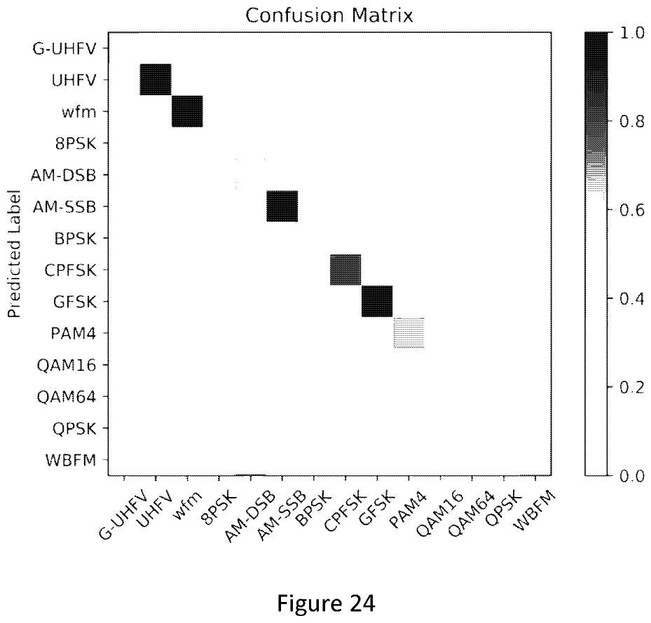

Advantageously, in this example the trainer 2300 parses both real and synthetic signal datasets to train the neural network on identifying features in spectrum data at different signal-to-noise ratios. In this regard, the CNN uses IQ data, frequency, bandwidth. SNRs, modulation type and timestamp as inputs from datafiles. 280. As discussed above, output 2306 from the trained model 2305 includes detected signal type (or spectrum anomaly) with an indicator of confidence in the labelling of features at a specific frequency. FIG. 24 shows an example of a resultant training confusion matrix which plots predicted label against true label.

As will be discussed below, the output 2306 may be used as a metric in determining the System Map, for example as new performing metrics used in comparing signal and environmental characteristics. The intention is that the metric provides an indication of context of cause in a cause/effect relationship (i.e. determine there is an underlying known signal type and use the accuracy of that determination as a metric).

Spectrum Sweep Detection Tool 1906

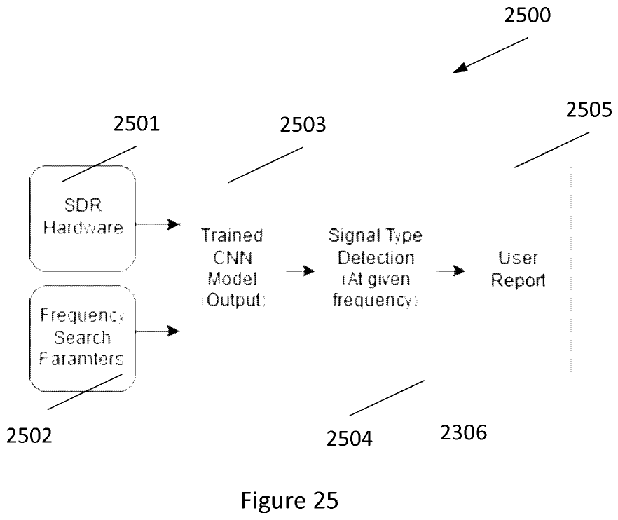

Once trained, in this example, the CNN model(s) 1906 may be used to detect signal types in real signals environments, and an example is shown in FIG. 25. For example, one or more models 2503 may be loaded and a sweep of one or more user-defined portions 2502 (e.g. frequency search parameters) of the spectrum begins using SDR hardware 2501. If the model(s) 2503 detect portions of the spectrum with patterns matching a trained signal type (for example, FSK) with a certain percentage confidence, the detection tool 2500 can display the confidence, frequency location and signal type 2504, for example, in a user report 2505.

In this example, the tool 1906 loads CNN models created with the spectrum trainer once they have been trained 1905 with real/synthetic data. Users can optionally to pre-define parameters 2502 such as enter start/stop frequency range, step size, gain of device (HackRF or RTL DR systems), crystal offset correction and confidence threshold when to report that a signal has been identified. In this example, the tool 1906 may autonomously detect and profile signals as they are detected.

The tool 1906 can sweep an arbitrary amount of spectrum and speed is dependent on hardware, step size selected, and volume of spectrum sampled.

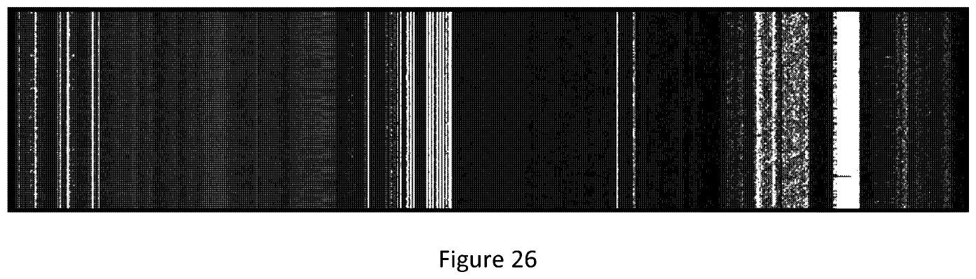

FIG. 26 is a 0-270 MHz waterfall plot sampled using SDR hardware showing a SDR spectrum sweep (without model comparisons operating), where approximately 30 passes of 8192 samples occurs every second. Increased sample size reduces processing speed.

GPS System Map Overview

The following data feeds were used in the generation of the GPS System Map in this example;
Local magnetic hazard
Space magnetic complexity and magnetic strength
Space electron hazard
Space proton hazard
Space X-ray hazard
Space alpha particle hazard
GPS signal-to-noise (SNR)
Constellation strength
Positional dilution of precision (PROP)
Horizontal dilution of precision (HDOP)
Vertical dilution of precision (VDOP)
Position uncertainty
Altitude uncertainty
Local luminosity

Selection of Training and Testing Datasets

Generating the GPS System Map was performed using training data from a single Data Logger GPS (“Logger 1”) which detected multiple interference events. Data collected at a 1 hz rate for multiple events are concatenated sequentially over the course of the day in the dataset. Individual data logging events range from 1-10 minutes each for a total of 80 k timesteps collected over the course of the experiment.

Testing the results of the System Map used data from “Logger 2” which was co-located within two meters of Logger 1 and collected data in parallel. Logger 1 and Logger 2 had different GPS chipsets in order to test the generality of the model—namely, if the System Map from Logger 1 maintains accuracy on Logger 2 it shows strong evidence that the model can accurately nowcast interference and other events with some degree of independence over hardware.

Finding the Optional Number of Modes

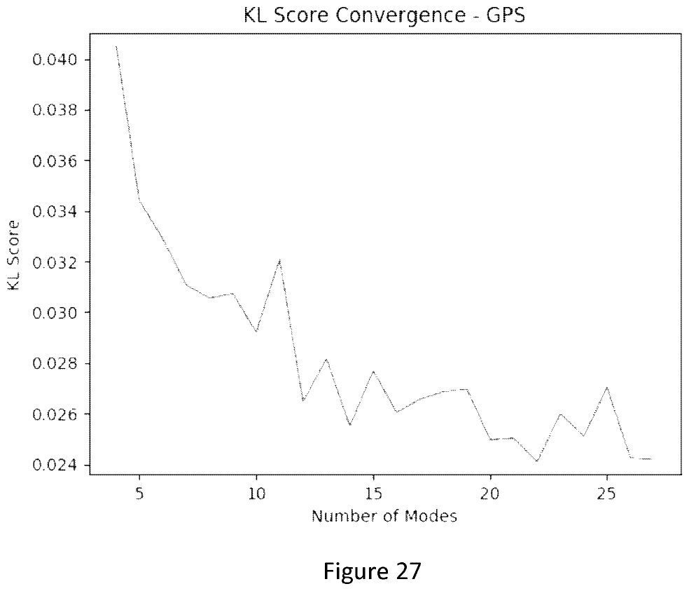

Tuning the GMM was conducted in parallel processing to test from 4 to 27 mixtures in the GMM. The accuracy of each mixture was measured using KL-Divergence between truth and prediction at each timestep in the training sample. FIG. 27 is a graphical representation of KL score and number of modes. As shown, locally optimal solutions are found at 14 and 22 mixtures.

The higher accuracy GMM requires more time to converge so the smaller mixture option gives flexibility in comparing accuracy vs cost. Notably the GMM with fewer mixtures is still reasonably accurate and useful for producing large volume of System Maps. Nevertheless, the larger dimensionality System Map is used in this experiment.

Training System Map

A test to validate the System Map was conducted in an autoregressive fashion by recreating the training dataset used to construct the model. Accurate recreation gives confidence in the cause-effect regressions justifying further testing.

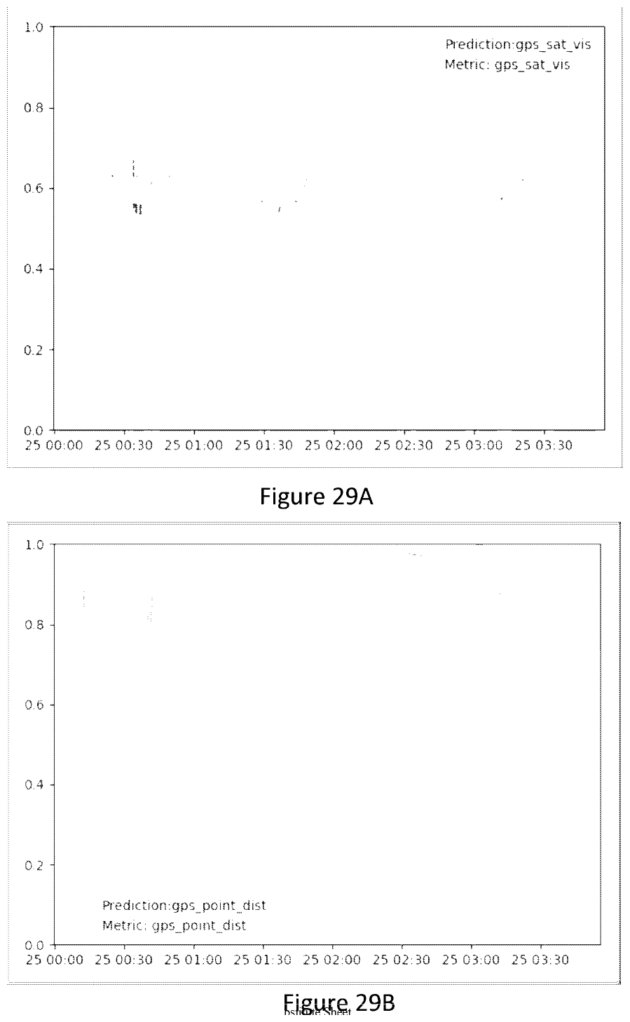

FIG. 29A shows number of satellites in view; and FIG. 29B shows the size of the GPS location uncertainty, with the solid blue trace representing the training set metric and the dashed red line representing the System Map (SM) prediction. Spike events at time 00:45 and 03:14 correspond to active interference events.

As shown, the number of satellites in view (FIG. 29A) has a false positive at time 03:00 but otherwise accuracy is extremely high.

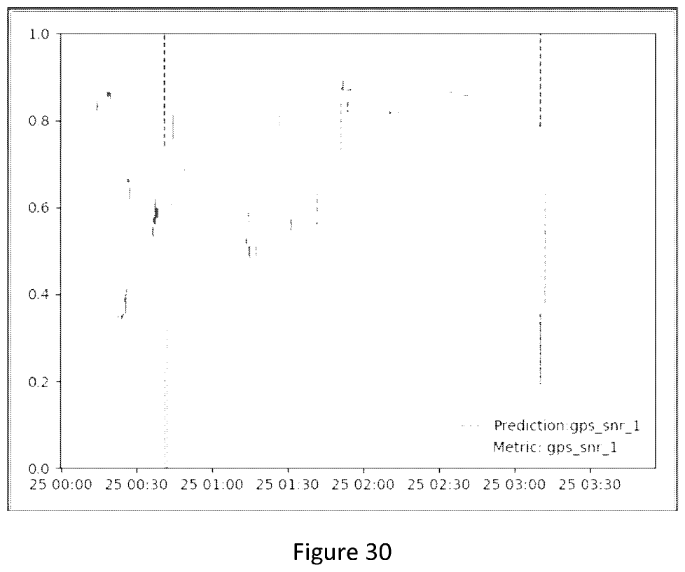

FIG. 30 is a plot of training (solid blue, line) and SM prediction (dashed red line) for the metric relating to SNR accuracy. While the training set is a noisy metric, the prediction shows strong accuracy and trending. A false negative at the start of the second interference which is recovered in the next timestep.

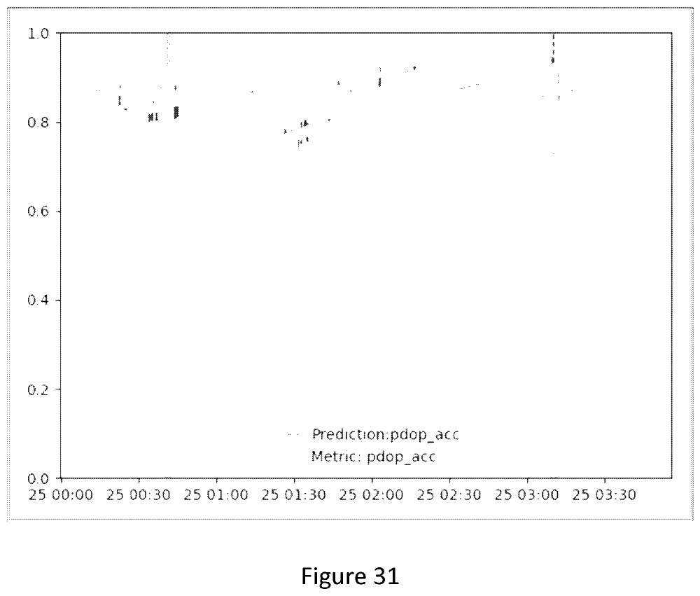

FIG. 31 is a plot of position dilution of precision (PROP) accuracy shoeing that the SM model predicts (dashed red line) the training metric (solid blue line) with very high accuracy, albeit with a missed interference shown at time 03:00.

Testing the System Map on New Data (Logger 2)

The System Map generated using Logger 1 was used on Logger 2 data to see if the model is cross platform to new hardware. As Logger 2 uses a different GPS chipset, accuracy shows generality of the solution used in a nowcasting fashion.

The process of generating metrics is as described above with reference to FIG. 19 and Logger 1.

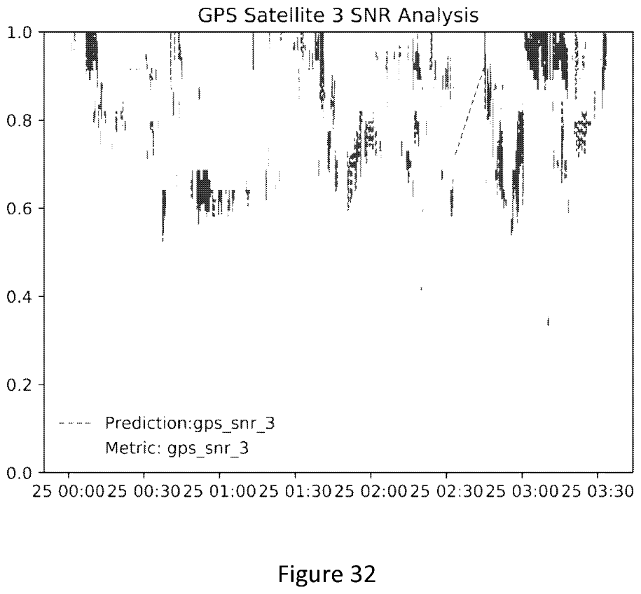

The System Map showed a reasonable accuracy with FIG. 32 showing a plot of Logger 2 derived metric (solid blue line) vs SM model prediction (dashed red line)) relating to GPS Satellite 3 SNR.

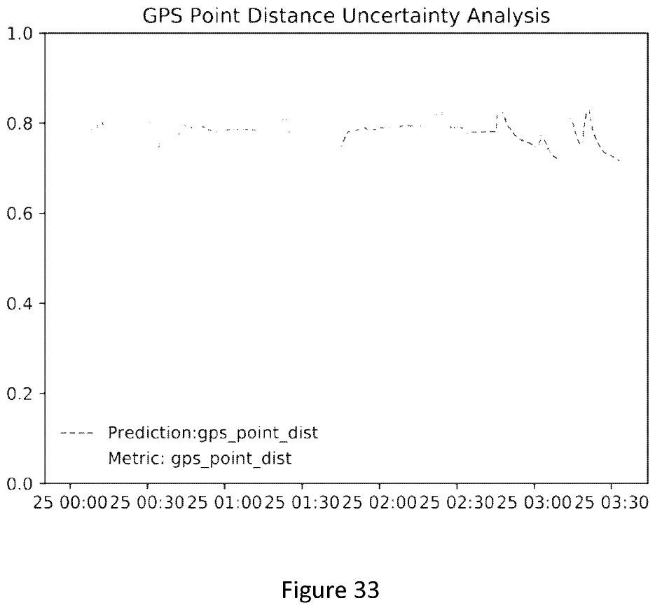

FIG. 33 compares GPS point distance uncertainty for the metric (solid blue line) and SM prediction (dashed red line). Highly accurate prediction of GPS point distance is shown, with a GPS interference occurred at the start and at time 25 00:30.

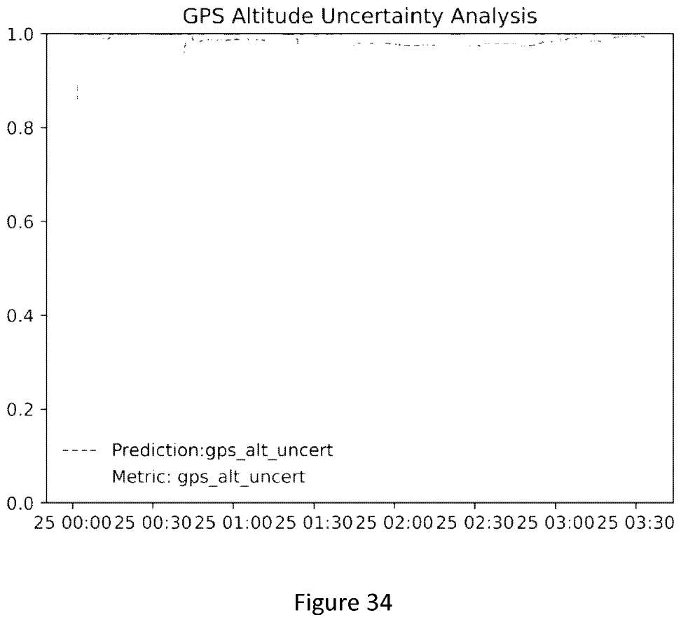

FIG. 34 is a plot relating to GPS altitude uncertainty and shows that the SM model produces a highly accurate prediction (red dashed line) of the GPS Altitude Uncertainty metric (blue solid line). GPS interference occurred at the start and at time 25 00:30.

Indeed, it appears that the relationships are sensible and show a highly appropriate response (FIGS. 32, 33, and 34).

An investigation of the System Map's DBN regressions (Direct Acyclic Graph, or DAG) show two of the GMM mixtures have states related to interference events. In these states the DBN showed strong relationships between SNR for various satellites (depending on the satellites in view) and either point distance uncertainty or altitude uncertainty. There were little to no relationships with PDOPs and regression of the PDOP function only partially converged, which suggests that the chipset in Data Logger 2 may have a slightly different interpretation for calculating PDOP. VDOP, interestingly, is highly accurate. Further details on the performance of System Maps generated in Examples 7 and 8 are provided below.

### EXAMPLE 7

In this example, a UHF Citizen Band (CB) CNN System Map (SM) is generated using real world radio data, synthetic data radio sets, and simulated interference events—for example, as described above in relation to the SDR spectrum trainer 1905.

Dataset Creation

Creation of datasets for UHF CB involved both real and simulated data components. Unperturbed and perturbed samples of a narrowband FM modulated voice signal were used for training the neural network component of the SM. As voice interference is typically regulated by law, the use of real data and simulated interference as described herein was used in testing.

To create the datasets for CNN training, USB-connected SDR hardware was linked to the real-time targeted radio dataset generator (as described above). An empty CB channel was selected, and short-duration voice snippets were sent while the data-collector software was sampling the spectrum. Bram Stoker's “Dracula” was utilised as source material for spoken samples. Several synthetic modulated samples which used randomised “Complete Works of William Shakespeare” samples for digital signals, and miscellaneous public domain .wav samples for analog signals were created. Using these samples, the following datasets were obtained for use in training the CNN:
Voice samples directly sampled by SDR equipment.
Voice samples sampled by SDR equipment and subjected to synthetic additive white
Gaussian Noise (a.k.a. synthetic noise interference).
Spectrum with absence of signal aka “noise”.
Miscellaneous synthetic modulated and labelled data types such as BPSK, QPSK, 8PSK and PAM 4

Experimental Conditions

Transmissions over UHF CB were conducted with approximately 20 m between handheld transceiver and established SDR and processing stack. Fifty samples per transmission period were collected, with each transmission period limited to 15 seconds. All transmissions were conducted in an indoor environment with direct line-of-sight to a wide-band discone antenna setup. Power output of handheld CB radios were fixed at 0.5 W as per manufacturer specification.

SDR gain was set to a fixed value of 20 dB which is also the maximum simulated gain utilized in dataset creation. This does not result in an SNR equal to 20 dB however proximity to receiving SDR equipment produced signal samples at adequately high levels for training. Local environment data-loggers are not utilised as metrics and maps developed for UHF CB typically depend on CNN outputs only along with SNR.

First the CNN was trained. Each sample of the IQ signal data was converted into a 2-dimensional matrix of 2×128 per data point. Samples were then stacked into time series format, i.e a 3-dimensional matrix of n×2×128 where n is the number of samples. For training the CNN, the samples are randomised and 80% of the data is kept for training the CNN while 20% remains for testing the CNN. The CNN outputs a vector per sample which is a vector of probabilities of a set of possible signal modulations. The output of the CNN is a prediction of over each modulation at each time step. The validation of the CNN is shown in FIG. 24.

In this example, the CNN training data has 132 k data points to train the System Map. 14 k data points were separated and used for testing the System Map. The volume of training data may be reduced unless environmental metrics and space weather metrics are added (such as in other examples). Due to the simulated nature of the Gaussian noise it is not yet meaningful to add environmental metrics in this case.

CNN Model Training

Since the System Map is trained on a mix of simulated and live data, this System Map had 15 metrics for modulations and one metric for SNR. Showing relationships between SNR and the modulation outputs provide a regression for how modulation estimates from the CNN respond to interference events. The relationship between SNR and aggregate outputs from the CNN is typically significant, and this is also represented in the State Vector.

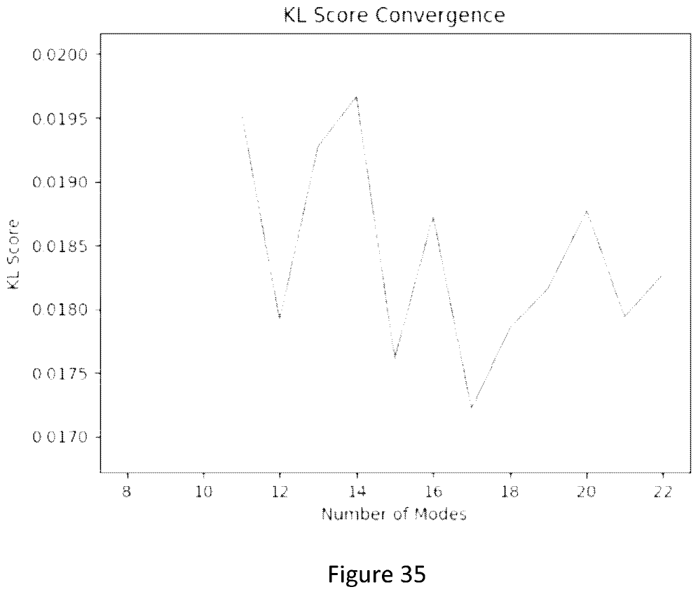

Tuning the GMM and FIG. 35 shows 17 mixtures as a local optimal. Notably the model did not converge with less than 11 mixtures which is likely due to the high dynamic and switching characteristics of signals, even after processing through the CNN. The model will likely need re-tuning when moving from simulated interference to live interference data.

Accuracy of the Training Set shows strong convergence of relationships between metrics output from the CNN, and this will be discussed further below. Metrics UFIFV (uninterfered) and G_UHFV (simulated interference) are typically significant metrics for this set.

CNN System Map Testing

Testing the CNN System Map involves removing last portion of the dataset (4000 timesteps) prior to training, then using the completed CNN System Map regressors to recreate the values at each time step. Accuracy in the separated data set shows proper ties of temporal invariance for System Maps monitoring live signals with simulated interference via Gaussian noise.

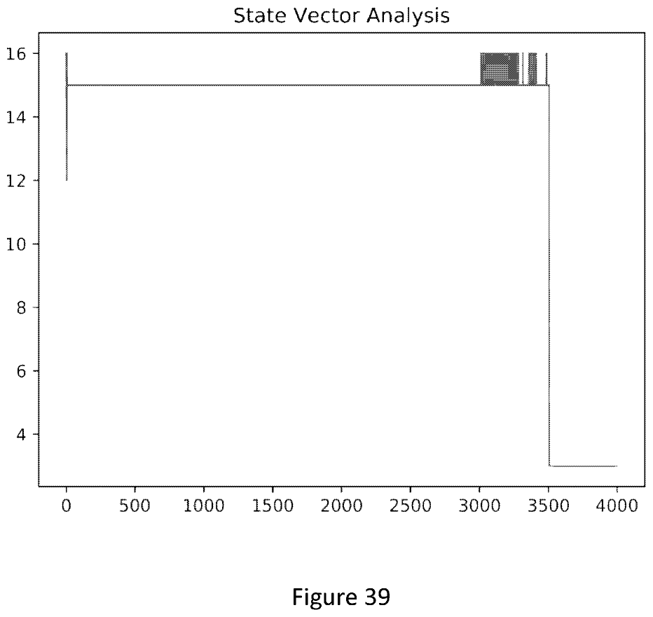

A state vector plot (FIG. 39) shows where simulated interference, occurs (Gaussian UHFV). Interference occurs at t=3500. Note there are multiple “non-interference” states are state 15 and 16 where transmissions are actively keyed. State 3 is UHF-V without Gaussian noise.

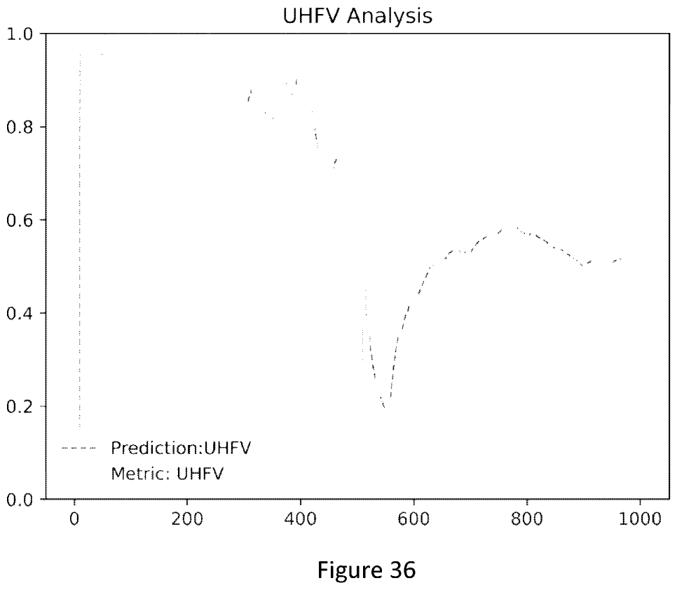

The System Map showed very high accuracy. FIGS. 36, 37, and 38 plot metrics (solid blue lines) and corresponding SM prediction (dashed red lines), and include specific responses related to the simulated interference. For example, regarding the UHFV analysis (FIG. 36), the metric prediction is accurate until the point of interference despite not being strong enough to calculate the noise, In this regard, the metric's benchmark likely needs improvement to account for such high noise. When interference begins a degradation of performance is shown along with tracking of the prediction. At the peak of interference the noise in the signal well paces the prediction and accuracy appears lost.

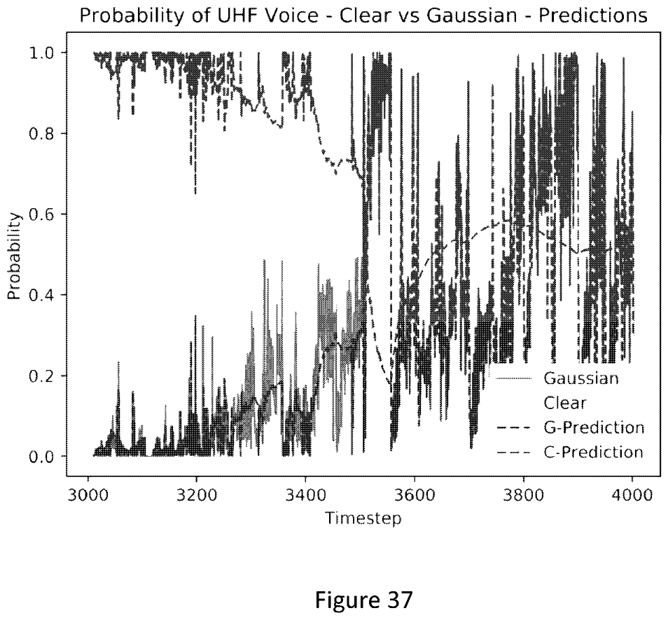

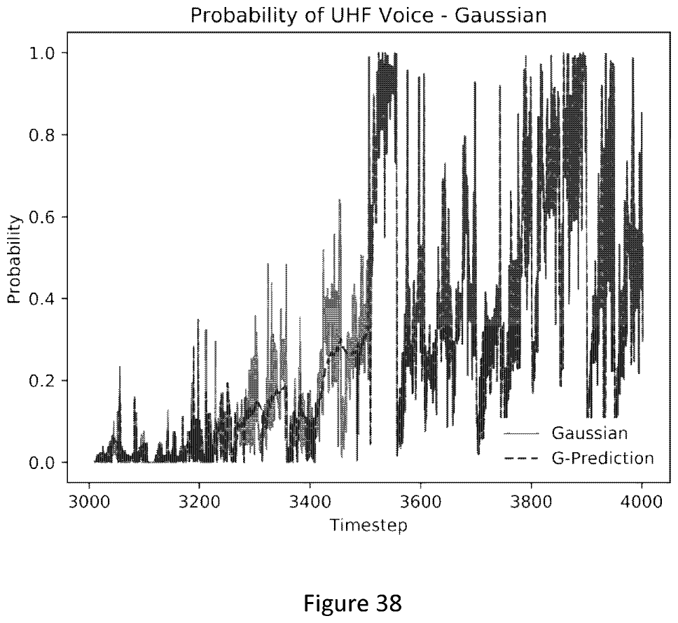

Incorporating a metric to track the signal over Gaussian noise (FIG. 37 and the close-up in FIG. 38) shows strong convergence of the model. With the CNN System Map, it is possible to converge to the noise in the metric if the interference signal is tracked along with the model. This is an exciting result cautioned only by the fact that the interference simulated, which may account for such a strong convergence of the interference metric.

Performance-Examples 6 and 7

Technical performance measures for GPS and CNN System Maps include accuracy, false positives, false negatives, convergence time and time invariance. These measures are discussed in more detail below.

Accuracy of GPS System Map

Accuracy of the model in conditions outside the training set, scored using Kullbeck Leibler (KL) divergence and via visual inspection. The smaller the number the better the solution (and greater confidence). Highly accurate metrics are KL=0.04 and below, partial convergence is between 0.04 and 0.06, while anything above 0.06 are considered non-accurate and need further consideration.

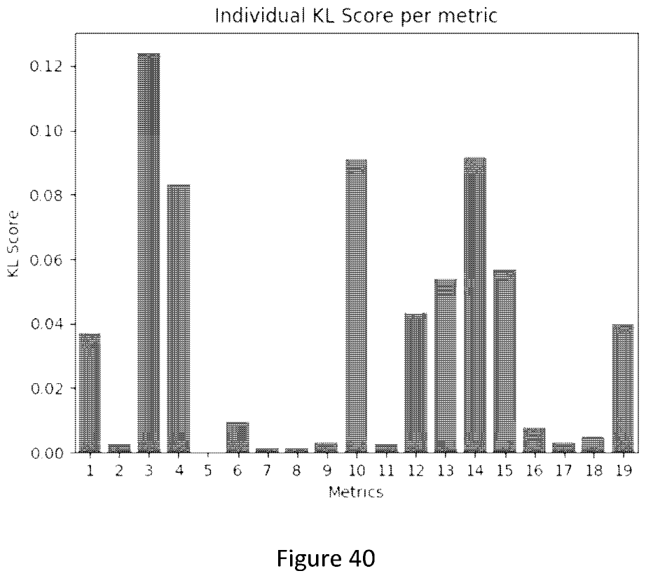

FIG. 40 is a plot of the accuracy convergence rollups of individual metrics in the GPS System Map. Values below 0.04 are considered useful in decision making. Partial solutions are between 0.04 and 0.06. Anything larger than 0.06 is not considered particularly useful. Metrics 12 through 15 in this example are metrics for SNR.

Accuracy is showing ˜95% for metrics relating to GPS accuracy (e.g. point distance, altitude, and VDOP/HDOP). PDOP showed accuracy of ˜75% however accuracy appears to increase strongly during interference indicating a partial convergence for that metric.

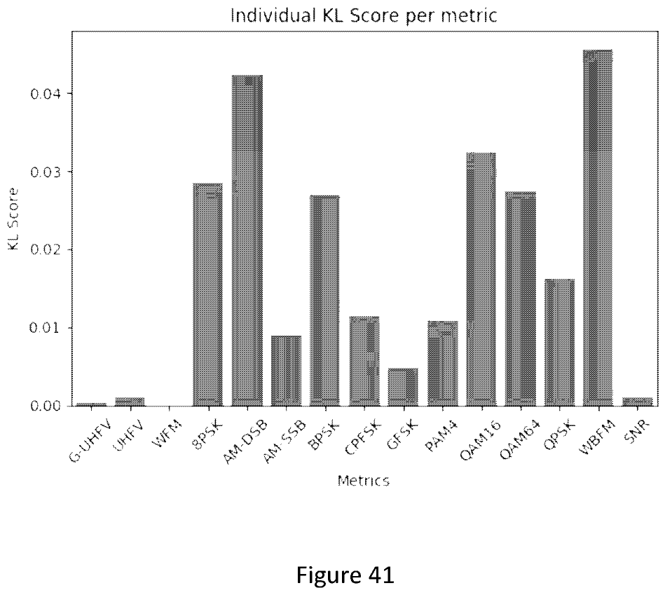

Accuracy convergence rollups of individual metrics in the CNN System Map are shown in FIG. 41. As shown, most are below 0.04 indicating usefulness in decision making. Note however that some accuracies may be artificially high due to the synthetic nature of the interference.

False Positive Rate

False positive rate is the number of times the model falsely identifies a interference event. False positives for the System Map as a while are identified via visible inspection over the time period in the state vector, which tracks the GMM mixture selected for that time step. Likewise, false positives in individual metrics help identify potential issues with the individual metric themselves for tuning and improvements of the System Map.

Example 6 GPS System Map False Positives

A visual inspection of the PDOP metric in the training had zero false positives while the test set showed 10-15 false positive “low accuracy” events which is likely a result of mi nor (and localised) overfitting affecting only the PDOP metric. SNRs exhibit occasional (1-3) false positives in the training data sets with 10-15 false positives in the test set. There may be some overfitting here as well but also SNR metrics exhibit reasonably high variance and is improvable with different benchmarks.

The GPS linear distance metrics showed no false positives in the independent test. Other GPS-related metrics also showed no false positives.

Example 7 CNN System Map False Positives

No False Positives are observable in the CNN System Map. However, simulated interference may have artificialities which will need further consideration in examples with a live interference event.

False Negative Rate

False negative rate refers to the number of times the model falsely disregards a valid interference event. As with false positives it is also useful to observe false negatives in individual metrics to help tune individual metrics equations and benchmarks as part of normal iteration of the model's regression terms.

Example 6 GPS System Map False Negatives

No false negatives were detected in the System Map state vector. False negatives for individual metrics are also consistent with the number of false positive rates in both training and testing data sets.

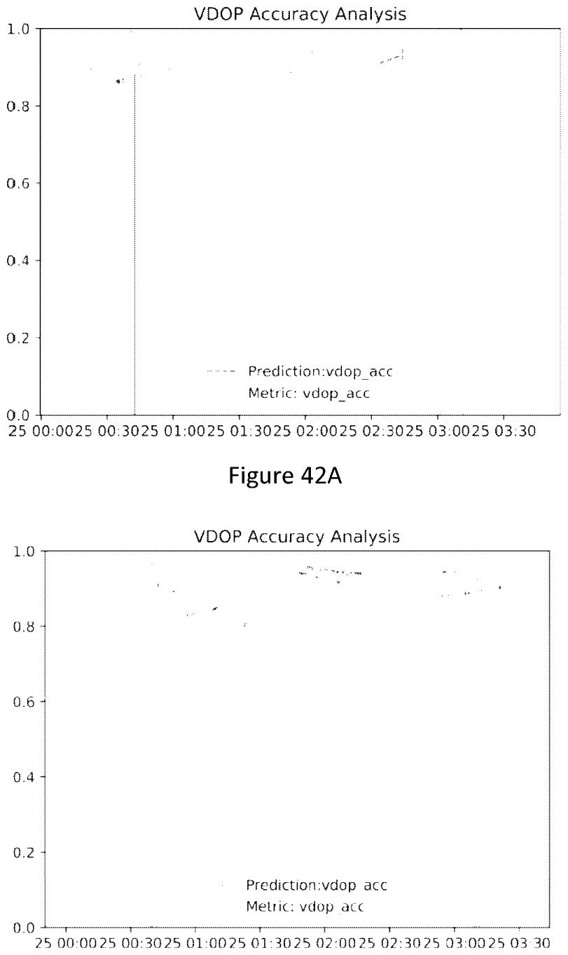

One apparent false negative is observable with the training data for VDOP (FIG. 42A). It appears that the hardware on Data Logger 1 is not affected by a interference event, but the System Map clearly identifies the actual event and predicts a performance not observed on the GPS chip. Most likely cause of this behaviour is the GPS hardware for the testing Data Logger experienced electronics lag, so the signal damage occurred in between data points in this instance. This is an example where the System Map identified a interference event which was not identified in hardware. FIG. 42B shows the VDOP accuracy analysis for the test data set indicating the interference event is Identified correctly.

Example 7 CNN System Map False Negatives 333. No False Negatives are observable in the CNN System Map. However, note that simulated interference may have

Convergence Time

Convergence time is the time required for the model to converge to an accurate solution.

The complexity is super exponential to the number of metrics (finding relationships in a DAG is an NP-Hard problem) and exponential to the number of mixtures in the GMM.

With the System Map data pipeline and modern accelerated hardware, it takes smaller GMM sizes roughly 1-hour per mixture to converge a solution with a data size of 80 k timesteps and 19 metrics in the GPS System Map. The full System Map takes four-days to converge and tune 27 mixtures.

The CNN System Map also took approximately one-hour to converge for each GMM mixture but with the first 8 mixtures not converging it took only 8 hours total per map even with 132 k data points and 16 metrics. The CNN System Map convergence time may increase when moving from simulated to live interference.

Time Invariance

Time Invariance is the accuracy of the solution over time, again measured with KL-di-vergence but also with an axis of ‘time since training’. The longer the cause-effect estimates keep accuracy the lower (hence cheaper) will be the model's maintenance requirements over time.

Time invariance is still being investigated, along with a minimal convergence for the GPS System Maps, and the CNN System Map is shoeing early evidence of temporal invariance with simulated interference injected on live data.

As shown, the ability for a GPS System Map trained on one Data Logger hardware has proven valid on a different Data Logger with a different GPS chipset. Generality is an important consideration as it suggests the GPS System Map has broad applicability across a family of chipsets, potentially reducing long term retraining costs.

### EXAMPLE 8

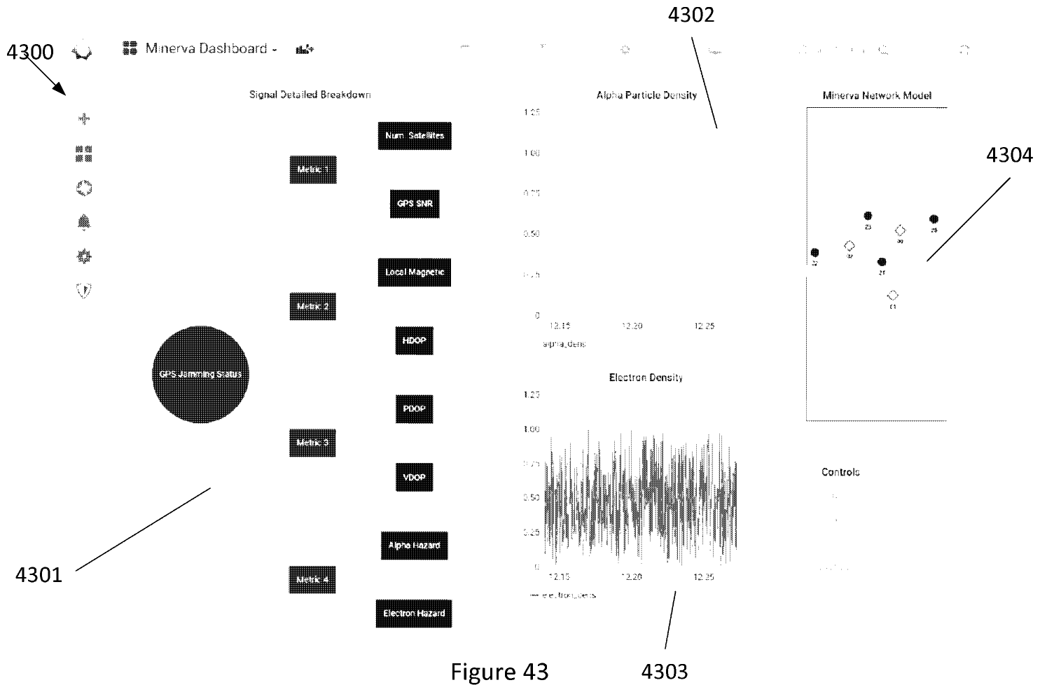

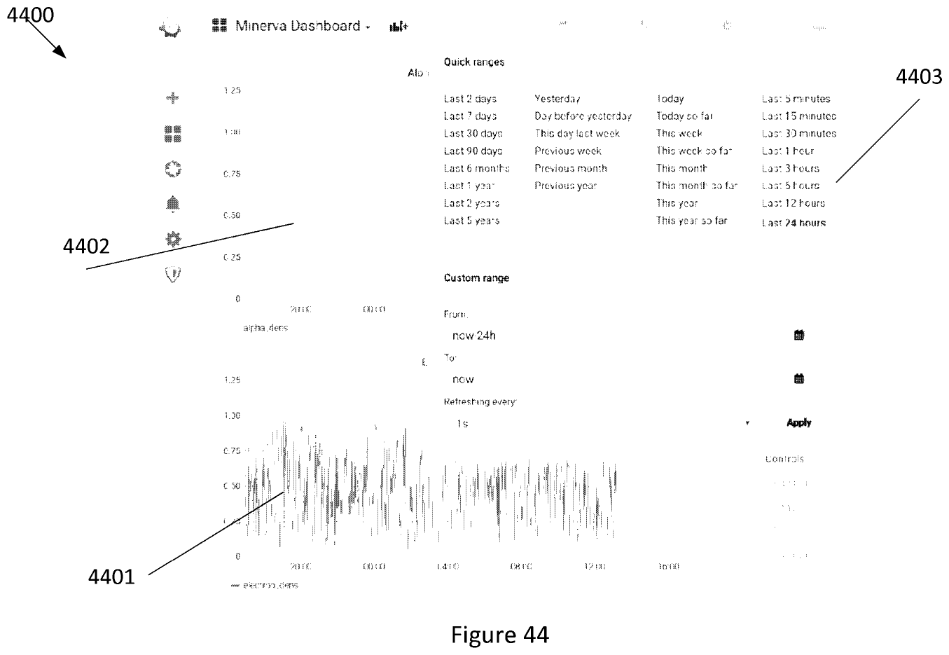

An example of a user interface for a system for assessing an electromagnetic signal will now be described with relation to FIGS. 43 and 44. In this example, a GPS System Map is determined, for example, in accordance with Example 6 above.

The user interface 4300 in FIG. 43 may be displayed by any suitable processing system, such as the user computer 102 described in the application above, in order provide access to the server 104. In any event, the graphical user interface 4300 includes a graphical representation 4301 (in this example, a flowchart) indicative of metrics and their most influential components for a certain timestamp. In this example:
Metric 1 is associated with the number of satellites and GPS signal-to-noise;
Metric 2 is associated with local magnetic factors, and HDOP;
Metric 3 is associated with PDOP and VDOP; and,
Metric 4 is associated with alpha and electron hazard.

In addition, the interface 4300 includes line graphs 4302, 4303, which in this example display alpha hazard and electron hazard signals captured between predefined start and end times.

A directed acyclic graph (DAC) for the current timestamp is shown at 4304, and represents the models trained and network-like graphs which are indicative of the Interconnectedness of metrics for that timestep.

Graphical user interface 4400 is an example showing the ability to define at 4403 the start and stop times when displaying signals such as alpha density 4402 and electron density 4401.

### SUMMARY

A system and method of assessment of aspects of one or more electromagnetic signals is described with reference to the examples herein. Beneficially, examples of identifying, detecting and/or measuring signal interference with the one or more electromagnetic signals are detailed, including facilitating quantitative assessment. In this regard, the system and method may be used to identify one or more sources of signal interference which can be advantageous in, for example, determining mitigation strategies and the like.

1. A method of assessment of aspects of one or more electromagnetic signals, the method including, in an electronic processing device:
receiving one or more environment data feeds relating to one or more of: cosmic, atmospheric, and local environmental conditions;
receiving one or more signal data feeds relating to the one or more electromagnetic signals;
determining a plurality of environment metrics and a plurality of signal metrics based on the environment data feeds and the signal data feeds respectively;
assessing relationships between environment metrics and signal metrics; and
identifying a likely source of interference in the electromagnetic signals based on a prediction of the assessed relationships.

2. A method according to claim 1, wherein the one or more data feeds are at least partially indicative of observable characteristics of an electromagnetic signal receiver.

3. A method according to claim 2, wherein the observable characteristics include any one or more of an altitude, a height, a vibration, a temperature, frequency response, and power.

4. A method according to claim 2, wherein the method includes, in the electronic processing device, determining a reference model at least partially indicative of relationships among metrics, the reference model being usable in assessing the relationships.

5. A method according to claim 4, wherein the reference model is generated using a System or Systems (SoS) approach, and the reference model includes a system of systems (SoS) model.

6. A method according to claim 4, wherein generating a reference model includes using one or more regression methods, wherein the relationships are at least partially indicative of causality.

7. (canceled)

8. (canceled)

9. (canceled)

10. A method according to claim 1, wherein the method includes, in the processing device, normalizing the metrics and the normalizing includes performing at least one regression using at least one numerical technique.

11. (canceled)

12. (canceled)

13. A method according to claim 10, wherein the normalizing includes at least one of:
normalizing raw values of the at least one data feeds and an absolute maximum of the raw values;
using at least one statistical tool to normalize the metrics, each of the metrics being scaled according to a common scale;
numerical conversion; and
using one or more machine learning models.

14. (canceled)

15. (canceled)

16. A method according to claim 1, wherein the metrics are determined at least in part using data indicative of at least one or more of a local magnetic field, space weather, an electromagnetic signal quality, an electromagnetic signal receiver quality, a positioning signal accuracy and a positioning signal.

17. A method according to claim 1, wherein the identifying includes at least one of:
determining at least one machine learning algorithm to thereby assess relationships between at least one of: the metrics; and, a time step;
clustering the metrics to thereby determine at least one state in accordance with the determined clusters, the state being at least partially indicative of a qualitative relationship between metrics;
in the electronic processing device, performing a numerical relationship regression for at least one of the clusters to thereby at least partially determine a causal relationship; and
in the computer processor, generating a representation indicative of at least one of:
the at least one state; and,
the at least one causal relationship.

18. (canceled)

19. (canceled)

20. (canceled)

21. (canceled)

22. A method according to claim 4, wherein the reference model includes one or more of:
an at least partially trained machine learning model;
at least one feature extraction reference model and at least one regression reference model;
an indication of causality among the relationships; and
an indication of qualitative and quantitative relationships among metrics.

23. A method according to claim 4, wherein the determining the reference model includes at least one of:
generating the reference model;
receiving the reference model from a remote processing device; and, retrieving the reference model from a store; and
wherein generating the reference model includes training the reference model using at least one of:
at least one of the plurality of metrics; and
at least one pre-determined metric.

24. (canceled)

25. (canceled)

26. (canceled)

27. (canceled)

28. (canceled)

29. (canceled)

30. A method according to claim 17, wherein method includes, in the processing device, identifying the source of interference using at least one of the state and the causal relationship.

31. (canceled)

32. (canceled)

33. (canceled)

34. (canceled)

35. (canceled)

36. A method according to claim 6, wherein the regression methods include at least one of a Dynamic Bayesian Network and a Gaussian Mixture Model.

37. (canceled)

38. A method according to claim 1, wherein the method includes, in the computer processor, determining at least one of cluster regression and relationship regression, and performing the identifying in real-time using the predetermined cluster regression and/or the relationship regression.

39. A method according to claim 1, wherein the method includes, in a computer processor, assessing the quantitative relationship indicators over time by comparing at least one of the predetermined cluster regression and the predetermined relationship regression with at least one of the cluster regression and the relationship regression, respectively.

40. A method according to claim 1, wherein the environment data feeds include data indicative of at least one of a local temperature, cosmic radiation and atmospheric radiation.

41. (canceled)

42. (canceled)

43. (canceled)

44. A method according to claim 1, wherein the electromagnetic signal is a radio frequency signal, and the radio frequency signal is received from one or more satellites or aircraft.

45. (canceled)

46. (canceled)

47. (canceled)

48. (canceled)

49. A system for assessing aspects of an electromagnetic signal, the system including:
one or more receivers for receiving one or more environment data feeds from one or more sources relating to cosmic, atmospheric and/or local environmental conditions;
one or more receivers for receiving one or more signal data feeds relating to one or more electromagnetic signals;
a mapping engine for mapping metrics derived from the data feeds; and
a regression engine for assessing relationships between selected mapped metrics so as to identify likely sources of signal changes.

50. A method according to claim 1, wherein an instance of interference is identified based on an anomaly in the prediction of the assessed relationships.
